(19) United States
(12) Patent Application Publication
(10) Pub. No.: US 2026/0329543 A1
(43) Pub. Date: Oct. 22, 2026

(54) SCALABLE ANALOG AND DIGITAL SYSTOLIC ARRAY ARCHITECTURES FOR ARITHMETIC OPERATIONS

(71) Applicant: Koushik Krishnan, Saratoga, CA (US)

(72) Inventor: Koushik Krishnan, Saratoga, CA (US)

(21) Appl. No.: 19/639,342

(22) Filed: Apr. 6, 2026

Related U.S. Application Data
(60) Provisional application No. 63/791,110, filed on Apr. 18, 2025.
(60) Provisional application No. 63/819,003, filed on Jun. 6, 2025.

(51) Int. Cl. G06F 7/544; G06F 15/80; G06F 17/16

(52) U.S. Cl. CPC G06F 7/5443; G06F 15/8046; G06F 17/16

(57) ABSTRACT

Scalable analog and digital systolic array architectures for arithmetic operations are provided. A computing device includes input interfaces to receive a first matrix of row vectors and a second matrix of column vectors. A processing array comprises processing elements arranged in PE rows and columns, where each row vector corresponds to a PE row and each column vector to a PE column. Distribution circuits concurrently apply row elements to all PEs in respective PE rows and column elements to all PEs in respective PE columns at each clock cycle. Each PE multiplies the row element with the column element and accumulates the product over clock cycles. An output interface extracts accumulated results from each PE to output a resultant matrix representing the arithmetic operation between the matrices.

### CROSS-REFERENCE TO RELATED APPLICATIONS/INCORPORATION BY REFERENCE

This application claims priority to U.S. Provisional Patent Application Ser. No. 63/791,110 filed on Apr. 18, 2025, and U.S. Provisional Patent Application Ser. No. 63/819,003 filed on Jun. 6, 2025, the entire content of which is hereby incorporated herein by reference.

### TECHNICAL FIELD

The disclosure relates to computing architectures and more particularly, to systolic array architectures for performing arithmetic operations such as multiply-and-accumulate and matrix multiplication.

### BACKGROUND

Modern computing systems face increasing demands for high-throughput arithmetic operations, particularly in applications such as machine learning, signal processing, and scientific computing. Matrix multiplication and multiply-and-accumulate operations form the computational foundation for many of these workloads. Traditional digital architecture often encounters limitations related to data movement between memory and processing units, which can impact latency and power consumption. Systolic array architectures have been developed to address some of these challenges by enabling data to flow through a grid of processing elements in a rhythmic, pipelined manner. Various approaches exist for implementing systolic arrays, each offering different tradeoffs in terms of area, power, and computational throughput.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

In various embodiments of the disclosure, a computing device is described. The computing device includes a first input interface configured to receive a first matrix comprising a plurality of row vectors. The computing device further includes a second input interface configured to receive a second matrix comprising a plurality of column vectors. The computing device also includes a processing array comprising a plurality of processing elements (PEs) arranged in PE rows and PE columns, wherein each row vector of the plurality of row vectors corresponds to a respective PE row of the PE rows, and each column vector of the plurality of column vectors corresponds to a respective PE column of the PE columns. The computing device additionally includes a first distribution circuit coupled to the first input interface and the processing array, wherein the first distribution circuit is configured to concurrently apply, at each clock cycle of a plurality of clock cycles, a respective row element from each row vector of the plurality of row vectors to all PEs of the respective PE row. The computing device further includes a second distribution circuit coupled to the second input interface and the processing array, wherein the second distribution circuit is configured to concurrently apply, at each clock cycle of the plurality of clock cycles, a respective column element from each column vector to all PEs in the respective PE column. Each PE of the plurality of PEs is configured to multiply the respective row element with the respective column element into a product and accumulate the product over the plurality of clock cycles to produce an accumulated result. The computing device also includes an output interface coupled to the processing array, wherein the output interface is configured to extract the accumulated result from each PE of the plurality of PEs to output a resultant matrix, and the resultant matrix represents an output of an arithmetic operation between the first matrix and the second matrix.

In various embodiments of the disclosure, a computing device is described. The computing device includes a first input interface configured to receive a first matrix comprising a plurality of first elements. The computing device further includes a second input interface configured to receive a second matrix comprising a plurality of second elements. The computing device also includes a processing array comprising a plurality of analog processing elements (PEs) arranged in PE rows and PE columns. Each PE of the plurality of PEs comprises a first input node configured to receive a first element of the plurality of first elements and to output the first element to a successive PE in a respective PE row of the PE rows after a clock cycle of a plurality of clock cycles. Each PE further comprises a pulse width modulation (PWM) circuit coupled to the first input node, the PWM circuit configured to convert the first element into a pulse signal based on the first element. Each PE also comprises a second input node configured to receive a second element of the plurality of second elements and to output the second element to a successive PE in a respective PE column of the PE columns after the clock cycle. Each PE additionally comprises a current generation circuit coupled to the second input node, wherein the current generation circuit is configured to generate a current based on the second element. Each PE further comprises a pulse-controlled switch coupled to the current generation circuit, wherein the pulse-controlled switch is configured to receive the pulse signal from the PWM circuit and to pass the current for a duration of the pulse signal. Each PE also comprises an integration circuit coupled to an output of the pulse-controlled switch, wherein the integration circuit is configured to integrate the current over the duration of the pulse signal to produce a product of the first element and the second element, and accumulate the product over the plurality of clock cycles to produce an accumulated result. The computing device also includes an output interface coupled to the processing array, wherein the output interface is configured to extract the accumulated result from each PE of the plurality of PEs to output a resultant matrix.

In various embodiments of the disclosure, a method for performing matrix multiplication is described. The method includes receiving a first matrix comprising a plurality of row vectors. The method further includes receiving a second matrix comprising a plurality of column vectors. The method also includes mapping each row vector of the plurality of row vectors to a respective processing element (PE) row of a processing array, and mapping each column vector of the plurality of column vectors to a respective PE column of the processing array, wherein the processing array comprises a plurality of PEs arranged in the PE rows and the PE columns. The method additionally includes, for each clock cycle of a plurality of clock cycles, concurrently applying a respective row element from each row vector of the plurality of row vectors to all PEs of the respective PE row, and concurrently applying a respective column element from each column vector of the plurality of column vectors to all PEs of the respective PE column. The method further includes, at each PE of the plurality of PEs, multiplying the respective row element with the respective column element to produce a product, and accumulating the product over the plurality of clock cycles to produce an accumulated result. The method also includes extracting the accumulated result from each PE of the plurality of PEs to output a resultant matrix representing a product of the first matrix and the second matrix.

The foregoing general description of the illustrative embodiments and the following detailed description thereof are merely exemplary aspects of the teachings of this disclosure and are not restrictive.

Additional technical features and benefits are realized through the techniques of the disclosure. Embodiments and aspects of the disclosure are described in detail herein and are considered a part of the claimed subject matter. For a better understanding, refer to the detailed description and the drawings.

### BRIEF DESCRIPTION OF THE DRAWINGS

The following description will provide details of preferred embodiments with reference to the following figures, wherein:

FIG. 1 is a block diagram that illustrates a computing device configured for performing arithmetic operations such as matrix multiplication, in accordance with an embodiment of the disclosure;

FIG. 2 is a block diagram that illustrates a systolic workflow using simultaneous operand application for matrix multiplication operations, irrespective of digital or analog processing element implementation, in accordance with an embodiment of the disclosure;

FIG. 3 is a diagram that illustrates an analog processing element implementation for a systolic array configuration, in accordance with an embodiment of the disclosure;

FIG. 4 is a diagram that illustrates an analog processing element implementation with an integration array located externally to the processing array, in accordance with an embodiment of the disclosure;

FIG. 5 is a block diagram that illustrates a bit-splicing architecture where each vector element is represented as a series of pulses with place value weighting implemented through repeated parallel processing element circuits, in accordance with an embodiment of the disclosure;

FIG. 6 is a block diagram that illustrates a processing array implementation utilizing the bit-splicing architecture of FIG. 5, in accordance with an embodiment of the disclosure;

FIG. 7 is a block diagram that illustrates a processing array configured for systolic workflow with staggered diagonal data arrangement, in accordance with an embodiment of the disclosure;

FIG. 8 is a diagram that illustrates an analog processing element implementation following the systolic workflow of FIG. 7, in accordance with an embodiment of the disclosure;

FIG. 9 is a block diagram that illustrates a digital processing element array implementation for matrix multiplication operations, in accordance with an embodiment of the disclosure; and

FIG. 10 is a flowchart depicting a method for performing matrix multiplication, in accordance with an embodiment of the disclosure.

### DETAILED DESCRIPTION

Modern computing systems face increasing demands for high-throughput arithmetic operations, particularly in domains such as machine learning, neural network inference, digital signal processing, and scientific computing. Among the most computationally intensive operations in these applications are matrix multiplication and multiply-and-accumulate (MAC) operations, which form the computational foundation for a wide range of algorithms. The performance and energy efficiency of computing systems performing these operations directly impacts the overall system capability and power consumption. A key bottleneck in conventional digital systems arises from the physical and architectural separation between memory and processing units, which necessitates frequent data transfers that increase latency and contribute significantly to power consumption. As transistor scaling approaches physical limits, the historical gains from increasing clock speeds or adding more cores are diminishing, prompting exploration into alternative computing paradigms that can reduce data movement, enhance parallelism, and leverage fundamentally different principles of computation.

Systolic array architectures have emerged as an approach for performing matrix multiplication and MAC operations with high parallelism and data reuse. In a systolic array, a plurality of processing elements (PEs) are arranged in a grid configuration, with data flowing through the array in a rhythmic, pipelined manner. Each PE performs a local computation, such as multiplying two operands and accumulating the product, and passes data to neighboring PEs. This architecture enables parallel processing across the array while minimizing centralized memory access. Systolic arrays differ from conventional compute-in-memory (CIM) architectures in that both operands are streaming through the array, whereas in CIM architectures one operand is stored resident in the location where computation happens while only one operand is moving. In systolic arrays, the PE stores the accumulated result while both operands shift to the next element after each clock cycle.

Traditional systolic array architectures employ a data shifting approach where operands propagate through the array from PE to PE over successive clock cycles. In such architectures, a first operand may enter from one edge of the array and shift horizontally through each PE row, while a second operand may enter from an orthogonal edge and shift vertically through each PE column. Each PE receives operands from neighboring PEs, performs a computation, and passes the operands to subsequent PEs. This data shifting approach introduces a pipeline warm-up latency because operands arrive at different PEs at different times, requiring a staggered diagonal data arrangement to ensure proper synchronization of operands at each PE location. The PE functions as an accumulator performing multiply-and-accumulate operations, where the PE multiplies two current operands, adds the product to the previously stored value, and creates a running sum where operands change while results accumulate. The capacitor or accumulator is not reset until all operands for a complete MAC operation have been processed.

The present disclosure describes computing devices that employ different approaches for systolic array operations, including both a simultaneous operand application approach and a traditional shift-register-based approach with analog processing elements. In the simultaneous operand application approach, a first distribution circuit concurrently applies a respective row element from each row vector of a first matrix to all PEs of a respective PE row at each clock cycle. Similarly, a second distribution circuit concurrently applies a respective column element from each column vector of a second matrix to all PEs in a respective PE column at each clock cycle. This approach differs from traditional systolic arrays where operands shift from PE to PE, as the operands are instead broadcast to all PEs in a respective row or column simultaneously. The distribution circuits may include shift register circuits configured to sequentially select successive row elements or column elements over the plurality of clock cycles, with the shift registers located externally to the processing array rather than within each PE.

The simultaneous operand application approach may eliminate the pipeline warm-up latency that exists in traditional shift-register-based systolic architectures. In traditional architectures, the staggered diagonal data arrangement introduces a latency of N−2 clock cycles, where N corresponds to the number of PEs in a row or column, before the first complete result is available. This latency arises from the first-time dead time due to zeros being flushed from the shifted data arrangement. The simultaneous operand application approach removes this latency because all PEs receive their respective operands at the same time, eliminating the need for staggered data arrangement and the associated warm-up period. The plurality of clock cycles for completing a matrix operation comprises N clock cycles, where N corresponds to the number of row elements in each row vector of the plurality of row vectors.

The present disclosure also describes a computing device that employs a traditional shift-register-based systolic flow with analog processing elements. In this approach, each analog processing element comprises a first input node configured to receive a first element and to output the first element to a successive PE in a respective PE row after a clock cycle, and a second input node configured to receive a second element and to output the second element to a successive PE in a respective PE column after the clock cycle. Each PE further comprises a pulse width modulation (PWM) circuit coupled to the first input node, the PWM circuit configured to convert the first element into a pulse signal based on the first element. A current generation circuit is coupled to the second input node and configured to generate a current based on the second element. A pulse-controlled switch is coupled to the current generation circuit and configured to receive the pulse signal from the PWM circuit and to pass the current for a duration of the pulse signal. An integration circuit is coupled to an output of the pulse-controlled switch and configured to integrate the current over the duration of the pulse signal to produce a product of the first element and the second element, and accumulate the product over the plurality of clock cycles to produce an accumulated result. The first input node may comprise a first shift register configured to delay the first element by the clock cycle before outputting the first element to the successive PE in the respective PE row, and the second input node may comprise a second shift register configured to delay the second element by the clock cycle before outputting the second element to the successive PE in the respective PE column. This shift-register-based analog implementation maintains the classical systolic data movement pattern where both operands flow through the array exactly like digital systolic architectures, with conversion to analog happening inside each PE cell and each PE requiring a clock signal for shift register operation.

The computing devices described herein may be implemented with either analog processing elements or digital processing elements, providing flexibility to select an implementation based on application requirements. For smaller array sizes, such as a 4×4 array, a digital implementation may provide sufficient performance with reduced design complexity. For larger array sizes or applications where power efficiency is a consideration, an analog implementation may offer advantages in computational density. For very large array sizes, such as a 10,000×10,000 array, a hybrid analog-digital approach may be employed where some processing arrays are implemented using digital processing elements and other processing arrays are implemented using analog processing elements. Both the simultaneous operand application approach and the shift-register-based approach may be implemented with analog or digital processing elements, enabling the architectures to be deployed across a range of array sizes and implementation technologies. Analog processing elements may perform multiplication using pulse width modulation to convert one operand into a pulse signal and a current generation circuit to convert the other operand into a current, with integration circuits accumulating the products over clock cycles. Digital processing elements may employ digital multipliers and accumulators to perform the same operations in the digital domain.

The scalability of the computing device extends from small arrays suitable for embedded applications to large arrays capable of handling high-dimensional matrix operations. The processing array may be configured with varying numbers of PE rows and PE columns based on the target application, with the PE array size fixed based on hardware configuration such that an N×N array produces an N×N output matrix. The first distribution circuit and second distribution circuit may be scaled accordingly to provide operands to the processing array. The computing device may further include a reset circuit coupled to the processing array, wherein each PE is configured to maintain the accumulated result during the plurality of clock cycles and reset the accumulated result after the plurality of clock cycles, with the accumulated result at each PE representing a dot product of a respective row vector and a respective column vector. The output interface may include an analog-to-digital converter (ADC) array for analog implementations, where the ADC array may comprise N parallel ADCs to digitize the accumulated result from a respective PE row per conversion cycle. In some embodiments, the integration array may be located external to the processing array, with integration capacitors coupled to respective PEs to accumulate products, enabling denser packing of processing elements while maintaining integration functionality in a dedicated area. In some embodiments, each analog processing element may comprise a first integration capacitor and a second integration capacitor with a switch configured to selectively couple the output of the pulse-controlled switch to one of the capacitors over successive arithmetic operations, enabling ping-pong buffering that eliminates idle time during fetch operations. In some embodiments, a bit-splicing architecture may be employed where each vector element is represented as a series of pulses with place value weighting implemented through repeated parallel processing element circuits, allowing the systolic array to operate at unit pulse rates with increased hardware to achieve faster operation. The computing device may support various arithmetic operations including square matrix multiplication, non-square matrix multiplication, matrix-vector multiplication, and convolution operations commonly used in convolutional neural networks and signal processing applications. This scalability, combined with the flexibility of simultaneous operand application or shift-register-based operand passing and the flexibility of analog or digital PE implementations, enables the computing device to address a broad range of computational workloads requiring matrix multiplication and MAC operations. The architecture may also support compute-in-memory implementations where data streams may come from memory with streaming and shifting happening outside the PE array, enabling weights, kernels, or activations to be stored in memory locations and streamed to the processing array. In some embodiments, signed number operations may be supported using a two's complement approach with a single capacitor initially set to a mid-voltage reference, where above mid-voltage indicates positive results and below mid-voltage indicates negative results.

In various embodiments of the disclosure, a computing device is described. The computing device includes a first input interface configured to receive a first matrix comprising a plurality of row vectors. The computing device further includes a second input interface configured to receive a second matrix comprising a plurality of column vectors. The computing device further includes a processing array comprising a plurality of processing elements (PEs) arranged in PE rows and PE columns. Each row vector of the plurality of row vectors corresponds to a respective PE row of the PE rows, and each column vector of the plurality of column vectors corresponds to a respective PE column of the PE columns. The computing device further includes a first distribution circuit coupled to the first input interface and the processing array. The first distribution circuit is configured to concurrently apply, at each clock cycle of a plurality of clock cycles, a respective row element from each row vector of the plurality of row vectors to all PEs of the respective PE row. The computing device further includes a second distribution circuit coupled to the second input interface and the processing array. The second distribution circuit is configured to concurrently apply, at each clock cycle of the plurality of clock cycles, a respective column element from each column vector to all PEs in the respective PE column. Each PE of the plurality of PEs is configured to multiply the respective row element with the respective column element into a product and accumulate the product over the plurality of clock cycles to produce an accumulated result. The computing device further includes an output interface coupled to the processing array. The output interface is configured to extract the accumulated result from each PE of the plurality of PEs to output a resultant matrix. The resultant matrix represents an output of an arithmetic operation between the first matrix and the second matrix.

In various embodiments of the disclosure, the first distribution circuit comprises a first shift register circuit configured to sequentially select successive row elements from each row vector of the plurality of row vectors over the plurality of clock cycles. The second distribution circuit comprises a second shift register circuit configured to sequentially select successive column elements from each column vector of the plurality of column vectors over the plurality of clock cycles.

In various embodiments of the disclosure, the first distribution circuit and the second distribution circuit are external to the processing array.

In various embodiments of the disclosure, the computing device further includes a reset circuit coupled to the processing array. Each PE of the plurality of PEs is configured to maintain the accumulated result during the plurality of clock cycles. Each PE of the plurality of PEs is further configured to reset the accumulated result at each PE of the plurality of PEs after the plurality of clock cycles. The accumulated result at each PE of the plurality of PEs represents a dot product of a respective row vector of the plurality of row vectors and a respective column vector of the plurality of column vectors.

In various embodiments of the disclosure, each PE of the plurality of PEs is an analog processing element that comprises a current generation circuit configured to generate a current having a magnitude based on the respective column element. The analog processing element further comprises a pulse-controlled switch coupled to the current generation circuit. The pulse-controlled switch is configured to receive a pulse signal having a duration based on the respective row element. The analog processing element further comprises an integration circuit coupled to an output of the pulse-controlled switch. The pulse-controlled switch is configured to pass the current via the output to the integration circuit for the duration of the pulse signal. The integration circuit is configured to integrate the current over the duration of the pulse signal to output a voltage signal representing the product of the respective row element and the respective column element.

In various embodiments of the disclosure, the first distribution circuit comprises a pulse width modulation (PWM) circuit configured to convert the respective row element into the pulse signal. The first distribution circuit comprises the PWM circuit for each PE row of the PE rows.

In various embodiments of the disclosure, the analog processing element further comprises an enable switch configured to selectively pass the accumulated result to the output interface for the extraction.

In various embodiments of the disclosure, the analog processing element comprises a first integration capacitor, a second integration capacitor, and a switch configured to selectively couple the output of the pulse-controlled switch to one of the first integration capacitor or the second integration capacitor over successive arithmetic operations. The first integration capacitor is configured to accumulate the product while the second integration capacitor is coupled to the output interface for the extraction.

In various embodiments of the disclosure, the output interface comprises an analog-to-digital converter (ADC) array coupled to the processing array. The ADC array is configured to digitize the accumulated result from each PE of the plurality of PEs.

In various embodiments of the disclosure, the ADC array comprises N parallel ADCs. N corresponds to a number of the PE columns. The ADC array is configured to digitize the accumulated result from a respective PE row of the PE rows per conversion cycle.

In various embodiments of the disclosure, the computing device further includes an integration array external to the processing array. The integration array comprises a plurality of integration capacitors. Each integration capacitor of the plurality of integration capacitors is coupled to a respective PE of the plurality of PEs. Each integration capacitor of the plurality of integration capacitors is configured to accumulate the product from the respective PE.

In various embodiments of the disclosure, each PE of the plurality of PEs is a digital processing element. The digital processing element comprises a digital multiplier configured to multiply the respective row element with the respective column element to produce the product. The digital processing element further comprises an accumulator configured to accumulate the product over the plurality of clock cycles to produce the accumulated result.

In various embodiments of the disclosure, each PE of the plurality of PEs receives the respective row element as a buffered signal from the first distribution circuit and receives the respective column element as a buffered signal from the second distribution circuit.

In various embodiments of the disclosure, the plurality of clock cycles comprises N clock cycles. N corresponds to a number of row elements in each row vector of the plurality of row vectors.

In various embodiments of the disclosure, the arithmetic operation is one of a matrix vector multiplication or a matrix-matrix multiplication operation.

In various embodiments of the disclosure, the second input interface is configured to receive the second matrix from a memory array. The second distribution circuit is configured to stream column elements of the second matrix from the memory to the processing array.

In various embodiments of the disclosure, a computing device is described. The computing device includes a first input interface configured to receive a first matrix comprising a plurality of first elements. The computing device further includes a second input interface configured to receive a second matrix comprising a plurality of second elements. The computing device further includes a processing array comprising a plurality of analog processing elements (PEs) arranged in PE rows and PE columns. Each PE of the plurality of PEs comprises a first input node configured to receive a first element of the plurality of first elements and to output the first element to a successive PE in a respective PE row of the PE rows after a clock cycle of a plurality of clock cycles. Each PE further comprises a pulse width modulation (PWM) circuit coupled to the first input node. The PWM circuit is configured to convert the first element into a pulse signal based on the first element. Each PE further comprises a second input node configured to receive a second element of the plurality of second elements and to output the second element to a successive PE in a respective PE column of the PE columns after the clock cycle. Each PE further comprises a current generation circuit coupled to the second input node. The current generation circuit is configured to generate a current based on the second element. Each PE further comprises a pulse-controlled switch coupled to the current generation circuit. The pulse-controlled switch is configured to receive the pulse signal from the PWM circuit and to pass the current for a duration of the pulse signal. Each PE further comprises an integration circuit coupled to an output of the pulse-controlled switch. The integration circuit is configured to integrate the current over the duration of the pulse signal to produce a product of the first element and the second element. The integration circuit is further configured to accumulate the product over the plurality of clock cycles to produce an accumulated result. The computing device further includes an output interface coupled to the processing array. The output interface is configured to extract the accumulated result from each PE of the plurality of PEs to output a resultant matrix.

In various embodiments of the disclosure, the first input node comprises a first shift register configured to delay the first element by the clock cycle before outputting the first element to the successive PE in the respective PE row. The second input node comprises a second shift register configured to delay the second element by the clock cycle before outputting the second element to the successive PE in the respective PE column.

In various embodiments of the disclosure, each PE of the plurality of PEs further comprises a clock input coupled to the first shift register and the second shift register. The clock input is configured to synchronize the outputting of the first element and the second element to the successive PE of the respective PE row and the successive PE of the respective PE row, respectively.

In various embodiments of the disclosure, the first input interface is configured to provide the plurality of first elements to PEs in a first PE column of the PE columns in a staggered diagonal arrangement. The second input interface is configured to provide the plurality of second elements to PEs in a first PE row of the PE rows in the staggered diagonal arrangement.

In various embodiments of the disclosure, the staggered diagonal arrangement introduces a latency of N−2 clock cycles. N corresponds to a number of the PE rows or a number of the PE columns.

In various embodiments of the disclosure, each PE of the plurality of PEs further comprises an enable switch coupled to the integration circuit. The enable switch is configured to selectively couple the accumulated result to the output interface for the extraction.

In various embodiments of the disclosure, the output interface comprises an analog-to-digital converter (ADC) array configured to digitize the accumulated result from each PE of the plurality of PEs.

In various embodiments of the disclosure, the computing device further includes a reset circuit coupled to the processing array. The reset circuit is configured to reset the accumulated result at each PE of the plurality of PEs after the resultant matrix is extracted by the output interface.

In various embodiments of the disclosure, a method for performing matrix multiplication is described. The method includes receiving a first matrix comprising a plurality of row vectors. The method further includes receiving a second matrix comprising a plurality of column vectors. The method further includes mapping each row vector of the plurality of row vectors to a respective processing element (PE) row of a processing array, and mapping each column vector of the plurality of column vectors to a respective PE column of the processing array. The processing array comprises a plurality of PEs arranged in the PE rows and the PE columns. For each clock cycle of a plurality of clock cycles, the method includes concurrently applying a respective row element from each row vector of the plurality of row vectors to all PEs of the respective PE row. For each clock cycle of the plurality of clock cycles, the method further includes concurrently applying a respective column element from each column vector of the plurality of column vectors to all PEs of the respective PE column. At each PE of the plurality of PEs, the method includes multiplying the respective row element with the respective column element to produce a product. At each PE of the plurality of PEs, the method further includes accumulating the product over the plurality of clock cycles to produce an accumulated result. The method further includes extracting the accumulated result from each PE of the plurality of PEs to output a resultant matrix representing a product of the first matrix and the second matrix.

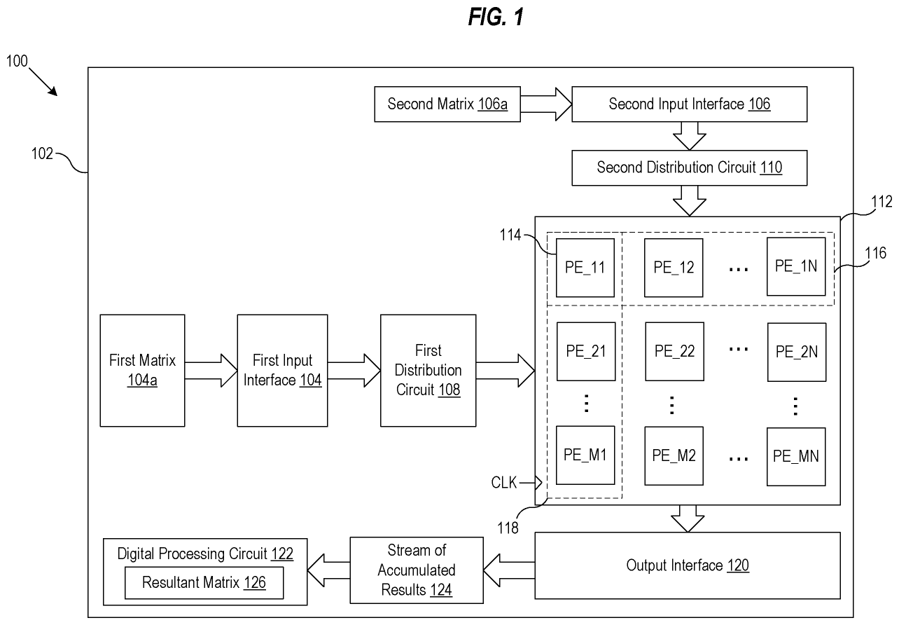

FIG. 1 is a block diagram 100 that illustrates a computing device 102 configured for performing arithmetic operations such as matrix multiplication, in accordance with an embodiment of the disclosure. With reference to FIG. 1, there is shown the block diagram 100 of the computing device 102. The computing device 102 includes a first input interface 104, a second input interface 106, a first distribution circuit 108, a second distribution circuit 110, a processing array 112, an output interface 120, and a digital processing circuit 122.

The computing device 102 may be configured to perform multiply-and-accumulate (MAC) operations or matrix-vector multiplication (MVM) operations. In the computing device 102, data flows through a grid of processing elements (PEs), each responsible for a small portion of the overall computation. This rhythmic, pipelined data movement eliminates the need for centralized memory access, enabling high-throughput and low-latency computation. The computing device 102 may be configured to receive input data streams representing two operand signals for the MVM operation, perform core analog or digital MAC operations in a systolic manner to generate the computed matrix-vector multiplication results.

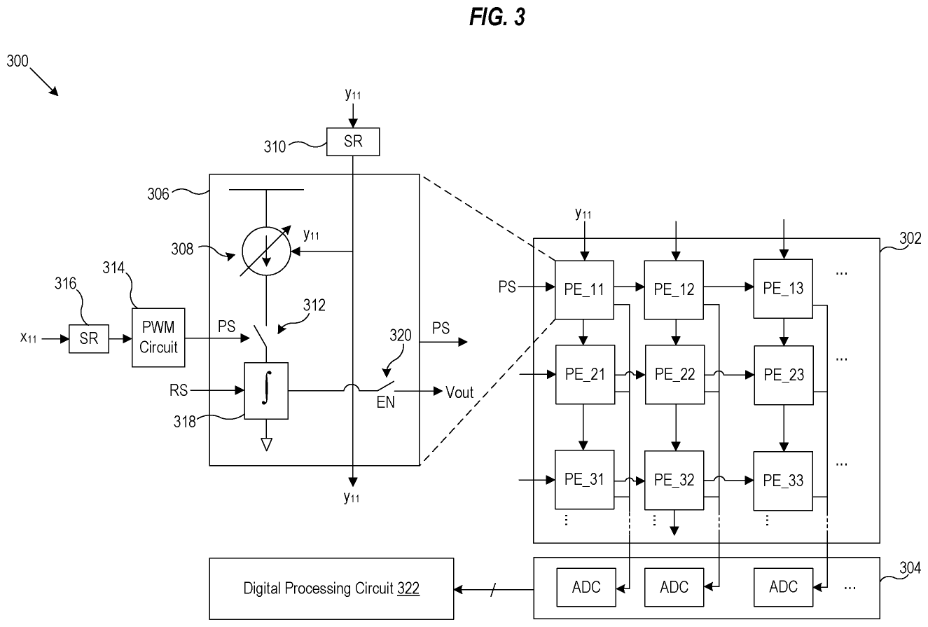

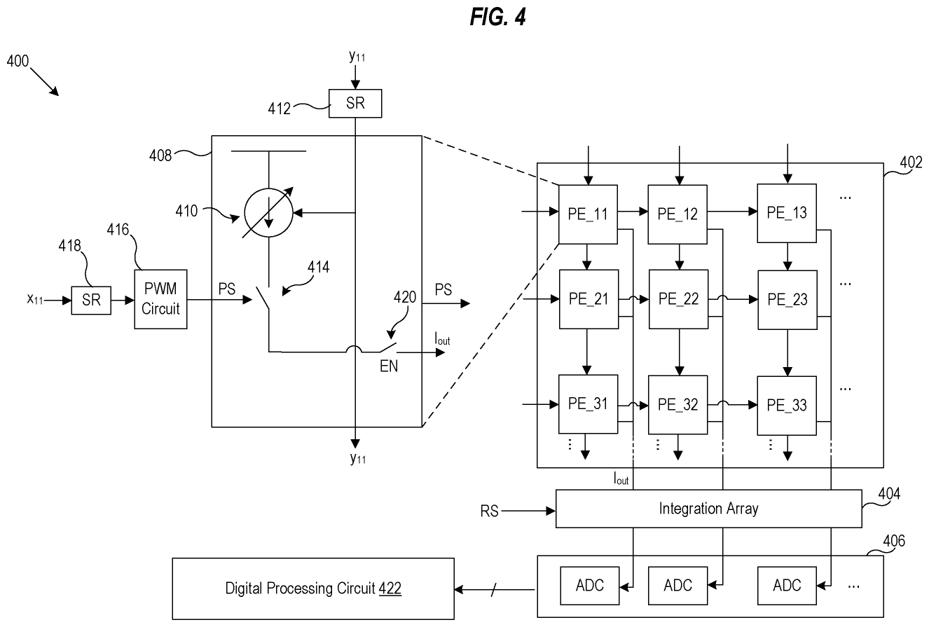

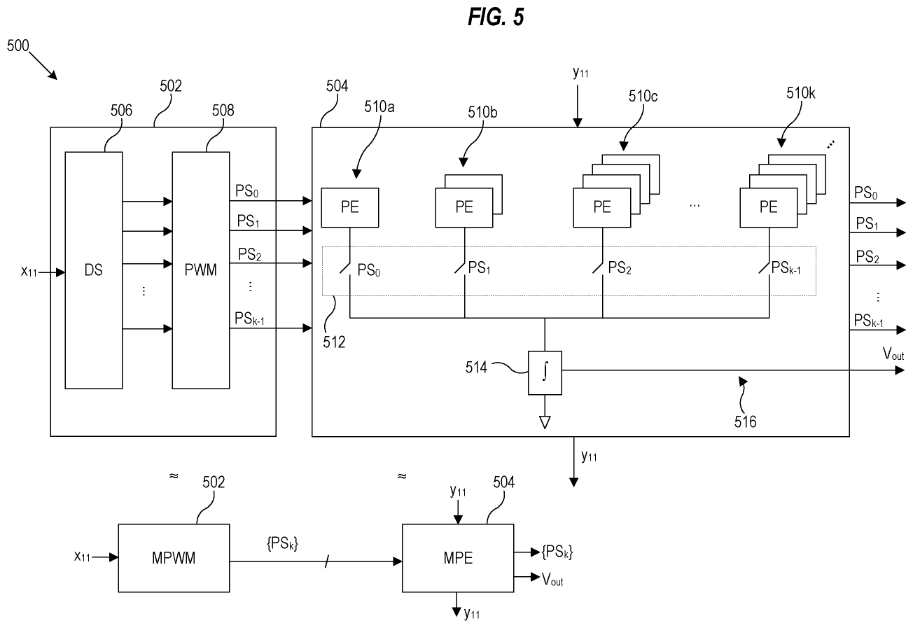

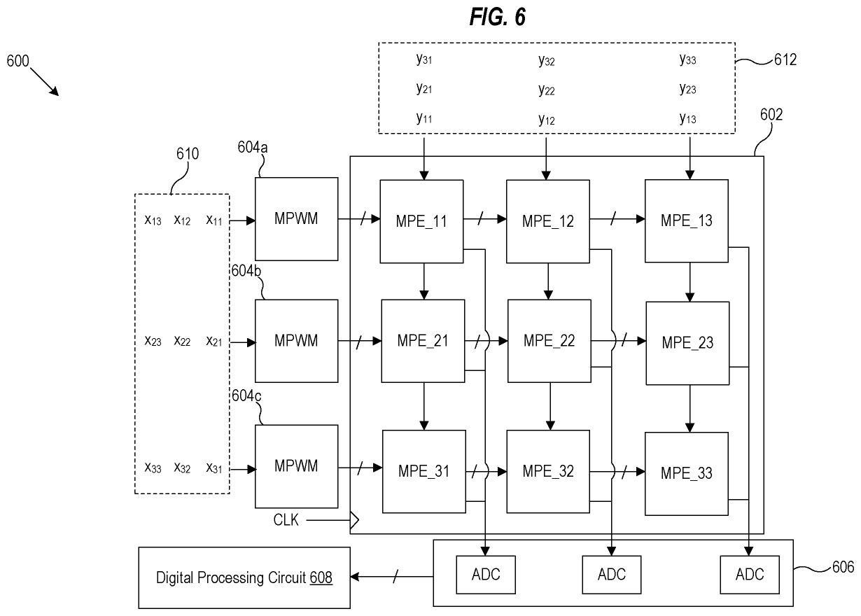

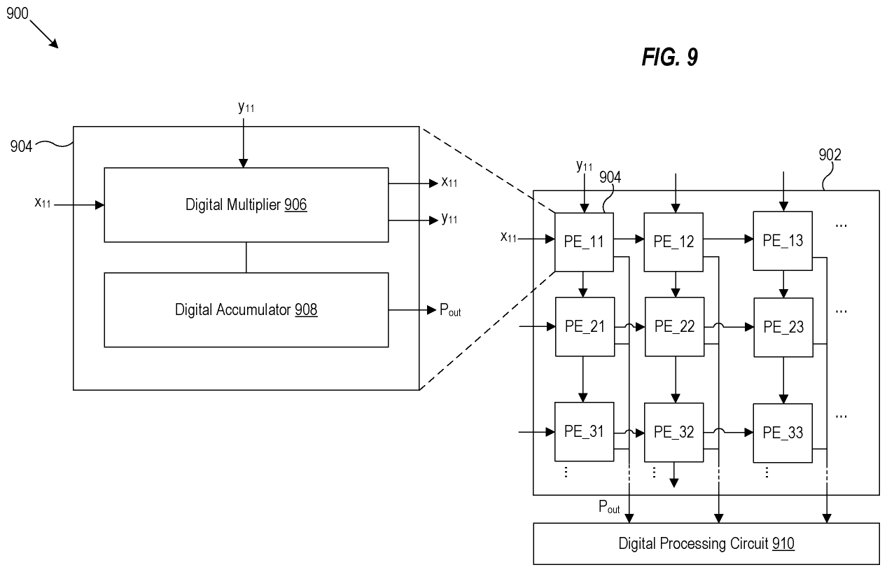

The computing device 102 may be implemented with either analog processing elements or digital processing elements, providing flexibility to select an implementation based on application requirements. For smaller array sizes, such as a 4×4 array, a digital implementation may provide sufficient performance with reduced design complexity. For larger array sizes or applications where power efficiency is a consideration, an analog implementation may offer advantages in computational density. For certain array sizes, such as a 10,000×10,000 array, a hybrid analog-digital approach may be employed. In certain implementation, the computing device 102 may comprise multiple processing arrays, wherein some processing arrays are implemented using digital processing elements as described with reference to FIG. 9 and other processing arrays are implemented using analog processing elements as described with reference to FIG. 3, FIG. 4, or the bit-splicing architecture of FIG. 5 and FIG. 6. Such hybrid implementations enable the computing device 102 to leverage the advantages of both analog and digital processing domains, where analog processing arrays may handle portions of the computation requiring high power efficiency and computational density while digital processing arrays may handle portions requiring higher precision or simpler design integration. The multiple processing arrays in a hybrid implementation may operate in parallel on different portions of a matrix operation, or may be configured in a pipelined arrangement where outputs from one processing array feed into another processing array.

The first input interface 104 is configured to receive a first matrix 104a comprising a plurality of row vectors. Each row vector of the plurality of row vectors contains a plurality of row elements that are to be used as operands in the arithmetic operation. The first input interface 104 may receive the first matrix 104a from external memory, a data bus, or other data sources. The first matrix 104a streams from a horizontal direction, with each row vector corresponding to a respective PE row of the processing array 112.

The second input interface 106 is configured to receive a second matrix 106a comprising a plurality of column vectors. Each column vector of the plurality of column vectors contains a plurality of column elements that are to be used as operands in the arithmetic operation. The second input interface 106 may receive the second matrix 106a from external memory, a data bus, or other data sources. The second matrix 106a streams from a vertical direction, with each column vector corresponding to a respective PE column of the processing array 112. In some embodiments, the second input interface 106 is configured to receive the second matrix 106a from a memory array, and the second distribution circuit 110 is configured to stream column elements of the second matrix 106a from the memory to the processing array 112, enabling compute-in-memory implementations where data streams may come from on-chip or off-chip memory. In such compute-in-memory implementations, weights, kernels, or activations may be stored in the memory location and streamed to the processing array 112.

With continued reference to FIG. 1, the processing array 112 comprises a plurality of processing elements (PEs) 114 arranged in PE rows 116 and PE columns 118. Each row vector of the plurality of row vectors corresponds to a respective PE row 116 of the PE rows 116, and each column vector of the plurality of column vectors corresponds to a respective PE column 118 of the PE columns 118. The PE array size is fixed based on hardware configuration, such that an N×N array produces an N×N output matrix for square matrix multiplication operations. For example, a 3×3 processing array 112 produces a 3×3 resultant matrix 126 when performing square matrix multiplication. The computing device 102 supports various arithmetic operations including square matrix multiplication where an M×K matrix is multiplied by a K×M matrix to produce an M×M resultant matrix, non-square matrix multiplication where an M×K matrix X_{M×K} is multiplied by a K×L matrix Y_{K×L} to produce an M×L resultant matrix Z_{M×L}, and matrix-vector multiplication where an M×K matrix is multiplied by a K×1 column vector to produce an M×1 resultant vector. The processing array 112 may be configured with M PE rows and L PE columns to accommodate non-square matrix operations, where the number of PE rows corresponds to the number of rows in the first matrix 104a and the number of PE columns corresponds to the number of columns in the second matrix 106a.

The processing array 112 receives a clock signal CLK for synchronizing operations across the processing elements 114. The processing elements 114 may be implemented as analog processing elements or digital processing elements depending on the application requirements and array size considerations. In hybrid implementations comprising multiple processing arrays, a first processing array may comprise analog processing elements while a second processing array may comprise digital processing elements, enabling the computing device 102 to partition computational workloads across different processing domains based on the characteristics of each portion of the computation. In analog implementations, each PE 114 is an analog processing element that comprises a current generation circuit configured to generate a current having a magnitude based on the respective column element, a pulse-controlled switch coupled to the current generation circuit and configured to receive a pulse signal having a duration based on the respective row element, and an integration circuit coupled to an output of the pulse-controlled switch. The pulse-controlled switch is configured to pass the current via the output to the integration circuit for the duration of the pulse signal, and the integration circuit is configured to integrate the current over the duration of the pulse signal to output a voltage signal representing the product of the respective row element and the respective column element. In digital implementations, each PE 114 is a digital processing element that comprises a digital multiplier configured to multiply the respective row element with the respective column element to produce the product, and an accumulator configured to accumulate the product over the plurality of clock cycles to produce the accumulated result.

The first distribution circuit 108 is coupled to the first input interface 104 and the processing array 112. The first distribution circuit 108 is configured to concurrently apply, at each clock cycle of a plurality of clock cycles, a respective row element from each row vector of the plurality of row vectors to all PEs 114 of the respective PE row 116. In various embodiments, the first distribution circuit 108 comprises a first shift register circuit configured to sequentially select successive row elements from each row vector of the plurality of row vectors over the plurality of clock cycles. For analog implementations, the first distribution circuit 108 comprises a pulse width modulation (PWM) circuit configured to convert the respective row element into the pulse signal, wherein the first distribution circuit 108 comprises the PWM circuit for each PE row 116 of the PE rows 116. This configuration provides fewer PWM circuits compared to implementations where PWM conversion occurs within each PE 114, as only one PWM circuit per row is required instead of one per PE. The second distribution circuit 110 is coupled to the second input interface 106 and the processing array 112. The second distribution circuit 110 is configured to concurrently apply, at each clock cycle of the plurality of clock cycles, a respective column element from each column vector of the plurality of column vectors to all PEs 114 in the respective PE column 118. In various embodiments, the second distribution circuit 110 comprises a second shift register circuit configured to sequentially select successive column elements from each column vector of the plurality of column vectors over the plurality of clock cycles. The first distribution circuit 108 and the second distribution circuit 110 enable simultaneous operand application where operands are broadcast to all PEs 114 in a respective row or column at each clock cycle, rather than shifting operands from PE to PE. This simultaneous operand application approach differs from traditional systolic arrays where operands shift from PE to PE, as the operands are instead broadcast to all PEs in a respective row or column simultaneously. In various embodiments, the first distribution circuit 108 and the second distribution circuit 110 are external to the processing array 112, with shift registers located externally to the processing array 112 rather than within each PE 114.

As shown in FIG. 1, each PE 114 of the plurality of PEs 114 is configured to multiply the respective row element with the respective column element into a product and accumulate the product over the plurality of clock cycles to produce an accumulated result. The PE 114 functions as an accumulator performing multiply-and-accumulate operations, where the PE 114 multiplies two current operands, adds the product to the previously stored value, and creates a running sum where operands change while results accumulate. The accumulated result is maintained during the plurality of clock cycles and represents a dot product of a respective row vector of the plurality of row vectors and a respective column vector of the plurality of column vectors upon completion of the plurality of clock cycles. For example, in a 3×3 array performing square matrix multiplication, PE₁₁ computes x₁₁·y₁₁+x₁₂·y₂₁+x₁₃·y₃₁, PE₁₂ computes x₁₁·y₁₂+x₁₂·y₂₂+x₁₃·y₃₂, and PE₂₁ computes x₂₁·y₁₁+x₂₂·y₂₁+x₂₃·y₃₁. For matrix-vector multiplication where a matrix X_{M×K} is multiplied by a vector v_{K×1}, each PE in a single column computes a respective element of the resultant vector, with PEᵢ₁ computing Σₖ₌₁^{K} xᵢₖ·vₖ for i=1, 2, . . . , M. In various embodiments, each PE 114 of the plurality of PEs 114 receives the respective row element as a buffered signal from the first distribution circuit 108 and receives the respective column element as a buffered signal from the second distribution circuit 110. In analog implementations, the integration circuit within each PE 114 may comprise a capacitor that is not reset until all operands for a complete MAC operation have been processed. Alternatively, each PE 114 may use an op-amp-based integrator with a feedback capacitor that accumulates charge across all operands of a MAC cycle before being reset.

In some embodiments, the analog processing element comprises a first integration capacitor, a second integration capacitor, and a switch configured to selectively couple the output of the pulse-controlled switch to one of the first integration capacitor or the second integration capacitor over successive arithmetic operations. The first integration capacitor is configured to accumulate the product while the second integration capacitor is coupled to the output interface 120 for the extraction, enabling ping-pong buffering that eliminates idle time during fetch operations. In some embodiments, the analog processing element further comprises an enable switch configured to selectively pass the accumulated result to the output interface 120 for the extraction.

The output interface 120 is coupled to the processing array 112 and is configured to extract the accumulated result from each PE 114 of the plurality of PEs 114 to output a resultant matrix 126. In analog implementations, the output interface 120 comprises an analog-to-digital converter (ADC) array coupled to the processing array 112, and the ADC array is configured to digitize the accumulated result from each PE 114 of the plurality of PEs 114. In various embodiments, the ADC array comprises N parallel ADCs, where N corresponds to a number of the PE columns 118, and the ADC array is configured to digitize the accumulated result from a respective PE row 116 of the PE rows 116 per conversion cycle. The N² outputs from the processing array 112 may be digitized in N cycles with N parallel ADCs, in one cycle with N² ADCs, or using a hybrid approach. In analog implementations, each PE 114 may further comprise an enable switch configured to selectively pass the accumulated result to the output interface 120 for the extraction, wherein the enable switch brings one element at a time to a common bus wire for row-by-row result extraction. The output interface 120 outputs a stream of accumulated results 124 to the digital processing circuit 122. The digital processing circuit 122 processes the stream of accumulated results 124 to produce the resultant matrix 126. The resultant matrix 126 represents an output of an arithmetic operation between the first matrix 104a and the second matrix 106a. The arithmetic operation is one of a square matrix multiplication, a non-square matrix multiplication, a matrix-vector multiplication, or a convolution operation. The digital processing circuit 122 may be implemented as a digital combinatorial circuit, a digital sequential circuit, a programmable logic device, a field programmable gate array (FPGA), an application-specific integrated circuit (ASIC), a digital signal processor (DSP), a microprocessor, a microcontroller, or any combination thereof.

In various embodiments, the plurality of clock cycles comprises K clock cycles, where K corresponds to a number of row elements in each row vector of the plurality of row vectors, representing the inner dimension of the matrix multiplication operation. The simultaneous operand application approach eliminates the pipeline warm-up latency that exists in traditional shift-register-based systolic architectures, where a staggered diagonal data arrangement introduces a latency of N−2 clock cycles before the first complete result is available. After K clock cycles, each PE 114 holds a complete accumulated result representing the dot product of the corresponding row vector and column vector. The output interface 120 may then extract the accumulated results from the PEs 114 for conversion and output as the resultant matrix 126.

In certain embodiments, the computing device 102 is configured to perform one-dimensional (1D) convolution operations and two-dimensional (2D) convolution operations commonly used in neural networks such as convolutional neural networks (CNNs), signal processing applications, and image processing applications. For 2D convolution operations in image processing, a convolution kernel of size Kₕ×K_{w} is applied to patches of an input image or feature map, where the kernel elements are flattened into a row vector and the image patch elements are flattened into a column vector, enabling the convolution operation to be performed as a matrix-vector multiplication. For CNN inference operations, the first matrix 104a may comprise weight kernels arranged as row vectors, and the second matrix 106a may comprise input activations or image patches arranged as column vectors, wherein each PE 114 computes a convolution output by accumulating the element-wise products of the kernel weights and the corresponding input patch elements. For 1D convolution operations in signal processing, a filter of length K is convolved with an input signal, where the filter coefficients form a row vector and successive segments of the input signal form column vectors, enabling efficient parallel computation of multiple convolution outputs.

The computing device 102 may further include a reset circuit coupled to the processing array 112, wherein each PE 114 of the plurality of PEs 114 is configured to maintain the accumulated result during the plurality of clock cycles and reset the accumulated result at each PE 114 of the plurality of PEs 114 after the plurality of clock cycles to prepare for a subsequent arithmetic operation. In various embodiments, a global reset is applied after a complete matrix operation, where all PEs 114 reset simultaneously. For PE activation control, if certain inputs are zero streams, the corresponding PE 114 will not accumulate any value and will function as a non-active element, enabling flexible utilization of the processing array 112 for matrices smaller than array dimensions of the processing array 112.

In some embodiments, the computing device 102 further includes an integration array external to the processing array 112. The integration array comprises a plurality of integration capacitors. Each integration capacitor of the plurality of integration capacitors is coupled to a respective PE 114 of the plurality of PEs 114, and each integration capacitor of the plurality of integration capacitors is configured to accumulate the product from the respective PE 114.

In hybrid implementations, the computing device 102 may comprise a first processing array implemented using analog processing elements as illustrated in FIG. 3 or FIG. 4, a second processing array implemented using digital processing elements as illustrated in FIG. 9, and optionally a third processing array implemented using the bit-splicing architecture as illustrated in FIG. 5 and FIG. 6. The multiple processing arrays in such hybrid implementations may be interconnected such that partial results from one processing array may be provided as inputs to another processing array, or the multiple processing arrays may operate independently on different portions of a larger matrix operation. The hybrid implementation enables the computing device 102 to optimize performance, power consumption, and precision by selecting the appropriate processing array type for each portion of the computational workload, where analog processing arrays utilizing the simultaneous operand application approach as shown in FIG. 3 and FIG. 4 may provide advantages in power efficiency and computational density, digital processing arrays as shown in FIG. 9 may provide advantages in precision and design simplicity, and bit-splicing processing arrays as shown in FIG. 5 and FIG. 6 may provide advantages in speed by shifting place value operations into the processing element array hardware.

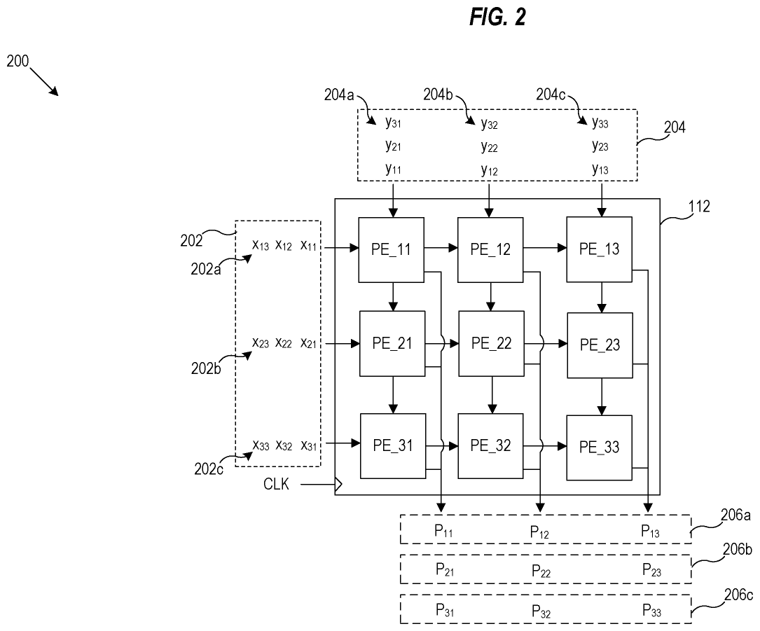

FIG. 2 is a block diagram 200 illustrating a systolic workflow using simultaneous operand application for matrix multiplication operations, in accordance with an embodiment of the disclosure. FIG. 2 is explained in conjunction with elements from FIG. 1. The block diagram 200 depicts the processing array 112 comprising a plurality of processing elements (PEs) arranged in a three-by-three grid configuration, with processing elements labeled PE_11 through PE_33. For sake of brevity, other components of the computing device 102 shown in FIG. 1, such as the first input interface 104, the second input interface 106, the first distribution circuit 108, the second distribution circuit 110, the output interface 120, and the digital processing circuit 122, are not shown in FIG. 2. The systolic workflow described with reference to FIG. 2 may be implemented with either analog processing elements or digital processing elements, as the simultaneous operand application approach is independent of the PE implementation type. Variations of PE implementations are described in further detail with reference to FIG. 3 and FIG. 4 for analog processing element configurations and FIG. 9 for digital processing element configurations. This configuration corresponds to the simultaneous operand application approach where operands are broadcast to all PEs in a respective row or column simultaneously, rather than shifting operands from PE to PE as in traditional systolic arrays.

With continued reference to FIG. 2, a first matrix 202 comprising a plurality of row vectors provides input operands from the left side of the processing array 112. The first matrix 202 comprises a first row vector 202a containing elements x₁₃, x₁₂, and x₁₁, a second row vector 202b containing elements x₂₃, x₂₂, and x₂₁, and a third row vector 202c containing elements x₃₃, x₃₂, and x₃₁. Each row vector of the plurality of row vectors corresponds to a respective PE row of the PE rows in the processing array 112. The first row vector 202a corresponds to the PE row containing processing elements PE_11, PE_12, and PE_13, the second row vector 202b corresponds to the PE row containing processing elements PE_21, PE_22, and PE_23, and the third row vector 202c corresponds to the PE row containing processing elements PE_31, PE_32, and PE_33. A second matrix 204 comprising a plurality of column vectors provides input operands from the top of the processing array 112. The second matrix 204 comprises a first column vector 204a containing elements y₃₁, y₂₁, and y₁₁, a second column vector 204b containing elements y₃₂, y₂₂, and y₁₂, and a third column vector 204c containing elements y₃₃, y₂₃, and y₁₃. Each column vector of the plurality of column vectors corresponds to a respective PE column of the PE columns in the processing array 112. The first column vector 204a corresponds to the PE column containing processing elements PE_11, PE_21, and PE_31, the second column vector 204b corresponds to the PE column containing processing elements PE_12, PE_22, and PE_32, and the third column vector 204c corresponds to the PE column containing processing elements PE_13, PE_23, and PE_33.

The processing array 112 receives a clock signal CLK that synchronizes the operation of the processing elements. A first distribution circuit is configured to concurrently apply, at each clock cycle of a plurality of clock cycles, a respective row element from each row vector of the plurality of row vectors to all PEs of the respective PE row. A second distribution circuit is configured to concurrently apply, at each clock cycle of the plurality of clock cycles, a respective column element from each column vector of the plurality of column vectors to all PEs in the respective PE column. Each PE of the plurality of PEs is configured to multiply the respective row element with the respective column element into a product and accumulate the product over the plurality of clock cycles to produce an accumulated result. The mathematical computations performed by each PE are shown in the block diagram 200, where each accumulated result represents a dot product of a respective row vector of the plurality of row vectors and a respective column vector of the plurality of column vectors. For the first PE row corresponding to the first row vector 202a, the accumulated results are computed as follows: P₁₁=y₁₁×x₁₁+y₂₁×x₁₂+y₃₁×x₁₃, P₁₂=y₁₂×x₁₁+y₂₂×x₁₂+y₃₂×x₁₃, and P₁₃=y₁₃×x₁₁+y₂₃×x₁₂+y₃₃×x₁₃. For the second PE row corresponding to the second row vector 202b, the accumulated results are computed as follows: P₂₁=y₁₁×x₂₁+y₂₁×x₂₂+y₃₁×x₂₃, P₂₂=y₁₂×x₂₁+y₂₂×x₂₂+y₃₂×x₂₃, and P₂₃=y₁₃×x₂₁ +y₂₃×x₂₂+y₃₃×x₂₃. For the third PE row corresponding to the third row vector 202c, the accumulated results are computed as follows: P₃₁=y₁₁×x₃₁+y₂₁×x₃₂+y₃₁×x₃₃, P₃₂=y₁₂×x₃₁+y₂₂×x₃₂+y₃₂×x₃₃, and P₃₃=y₁₃×x₃₁+y₂₃×x₃₂+y₃₃×x₃₃.

As further shown in FIG. 2, an output interface is coupled to the processing array 112 and is configured to extract the accumulated result from each PE of the plurality of PEs to output a resultant matrix. The output of the processing array 112 comprises a first output vector 206a containing accumulated results P₁₁, P₁₂, and P₁₃, a second output vector 206b containing accumulated results P₂₁, P₂₂, and P₂₃, and a third output vector 206c containing accumulated results P₃₁, P₃₂, and P₃₃. The first output vector 206a, the second output vector 206b, and the third output vector 206c collectively represent the resultant matrix, and the resultant matrix represents an output of an arithmetic operation between the first matrix 202 and the second matrix 204.

In the simultaneous operand application approach illustrated in FIG. 2, the first distribution circuit comprises a first shift register circuit configured to sequentially select successive row elements from each row vector of the plurality of row vectors over the plurality of clock cycles. The second distribution circuit comprises a second shift register circuit configured to sequentially select successive column elements from each column vector of the plurality of column vectors over the plurality of clock cycles. The first distribution circuit and the second distribution circuit are external to the processing array 112, with shift registers located outside the processing array 112 rather than within each PE. Each PE of the plurality of PEs receives the respective row element as a buffered signal from the first distribution circuit and receives the respective column element as a buffered signal from the second distribution circuit. In this configuration, there is no shifting of data within the PE, as PWM conversion and shift register operations occur outside the processing array 112.

Each PE of the plurality of PEs is configured to maintain the accumulated result during the plurality of clock cycles. The accumulated result at each PE of the plurality of PEs represents a dot product of a respective row vector of the plurality of row vectors and a respective column vector of the plurality of column vectors. The plurality of clock cycles comprises N clock cycles, where N corresponds to a number of row elements in each row vector of the plurality of row vectors. For the three-by-three configuration shown in FIG. 2, N equals three, and each PE accumulates products over three clock cycles to produce the complete dot product result. The simultaneous operand application approach eliminates the pipeline warm-up latency that exists in traditional shift-register-based systolic architectures, where a staggered diagonal data arrangement introduces a latency of N−2 clock cycles before the first complete result is available. In the simultaneous operand application approach, the matrix-vector multiplication (MVM) results are stored in N cycles, and therefore the MVM cycles equal N, as opposed to 2N−2 cycles required in traditional systolic arrays with staggered diagonal data arrangement. After the N clock cycles for computation, fetch cycles are required to retrieve the accumulated results from the PEs to the output interface. The fetch cycles equal N when N parallel fetch operations are performed, where N outputs are read in parallel per fetch cycle. For an N×N processing array producing N² outputs, the accumulated results may be digitized in N cycles using N parallel analog-to-digital converters (ADCs), in one cycle using N² ADCs, or using a hybrid approach. Subsequent matrix multiplication operations may complete every N cycles through pipelined throughput once the initial computation is complete.

FIG. 3 is a diagram 300 illustrating an analog processing element implementation for a systolic array configuration, in accordance with an embodiment of the disclosure. FIG. 3 is explained in conjunction with elements from FIG. 1 and FIG. 2. The diagram 300 depicts a processing array 302 comprising a plurality of analog processing elements (PEs) arranged in PE rows and PE columns, with processing elements labeled PE_11, PE_12, PE_13 in a first row, PE_21, PE_22, PE_23 in a second row, and PE_31, PE_32, PE_33 in a third row. An ADC array 304 is coupled to the processing array 302 and is configured to digitize the accumulated result from each PE of the plurality of PEs. A digital processing circuit 322 is coupled to the ADC array 304 to receive and process the digitized output signals. The configuration shown in FIG. 3 corresponds to an analog PE implementation with simultaneous operand application, where the PWM circuit and shift registers are located externally to the processing array 302, providing advantages in latency, area, and power consumption compared to traditional digital systolic array architectures.

With continued reference to FIG. 3, a processing element 306 is shown in expanded detail on the left side of the diagram 300. The processing element 306 is an analog processing element that comprises a current generation circuit 308 configured to generate a current having a magnitude based on the respective column element. The current generation circuit 308 may be implemented as a digital-to-current converter (IDAC) that receives a column element input y₁₁ and generates a corresponding current signal. In various embodiments, the column element y₁₁ may be retrieved from a memory array, enabling analog compute-in-memory (ACIM) implementations where weights, kernels, or activations are stored in memory and streamed to the current generation circuit 308. A shift register 310 is positioned at the top of the processing element 306 and receives the vertical input signal y₁₁. The shift register 310 is configured to buffer the column element for distribution to the processing element 306, with the shift register 310 located externally to the processing element 306 in the simultaneous operand application configuration.

The processing element 306 further comprises a pulse-controlled switch 312 coupled to the current generation circuit 308. The pulse-controlled switch 312 is configured to receive a pulse signal PS having a duration based on the respective row element. A PWM circuit 314 is coupled to a shift register 316 that receives the horizontal input signal x₁₁. The PWM circuit 314 is configured to convert the first element into a pulse signal based on the first element. In the simultaneous operand application configuration, the PWM circuit 314 and the shift register 316 are located externally to the processing array 302, with a single PWM circuit provided per PE row rather than one PWM circuit per PE. This external placement of the PWM circuit 314 simplifies the processing element 306 design, reduces the total number of PWM circuits required, and decreases the overall area and power consumption of the processing array 302. The pulse signal PS is broadcast to all PEs in the respective PE row simultaneously, and the pulse-controlled switch 312 is configured to pass the current via an output to an integration circuit 318 for the duration of the pulse signal PS.

As further shown in FIG. 3, the integration circuit 318 is coupled to an output of the pulse-controlled switch 312. The integration circuit 318 is configured to integrate the current over the duration of the pulse signal to produce a product of the first element and the second element. The integration circuit 318 is further configured to accumulate the product over the plurality of clock cycles to produce an accumulated result. The processing element 306 further comprises an enable switch 320 coupled to the integration circuit 318. The enable switch 320 is configured to selectively couple the accumulated result to the output interface for the extraction. The enable switch 320 is used for data extraction to the ADC array 304 by bringing one processing element at a time to a common bus wire while all other enables are set to zero, allowing row-by-row result extraction.

The simultaneous operand application configuration illustrated in FIG. 3 provides reduced latency compared to traditional systolic array architectures. In traditional systolic arrays with staggered diagonal data arrangement, a latency of N−2 clock cycles is introduced before the first complete result is available due to the pipeline warm-up period required for operands to propagate through the array. The simultaneous operand application approach eliminates this pipeline warm-up latency because all PEs receive their respective operands at the same time, with matrix-vector multiplication (MVM) results stored in N cycles rather than 2N−2 cycles required in traditional systolic arrays. This latency reduction is achieved because there is no shifting of data within the PE, as the pulse signal PS and column element y₁₁ are input directly to the processing element 306 from external distribution circuits.

For an N×N processing array, this approach requires only N PWM circuits instead of N² PWM circuits, resulting in reduced area and power consumption. The simplified PE design achieved by moving the PWM circuit 314 and shift registers external to the processing element 306 enables denser packing of processing elements within the processing array 302 and reduces the complexity of clock distribution, as the clock signal is managed externally rather than requiring distribution to every individual processing element.

In various embodiments, the second input interface is configured to receive the second matrix from a memory array, and the second distribution circuit is configured to stream column elements of the second matrix from the memory to the processing array 302, enabling analog compute-in-memory (ACIM) implementations. In such ACIM implementations, the column elements y₁₁, y₂₁, y₃₁, and so forth may be stored in on-chip or off-chip memory and streamed to the current generation circuit 308 of each processing element 306. This configuration allows weights, kernels, or activations to be stored in the memory location and streamed to the processing array 302 for matrix multiplication operations, with the streaming and shifting operations occurring outside the processing element 306. The ACIM implementation leverages the simultaneous operand application approach where both operands may come from memory, with the current generation circuit 308 converting the stored column elements into current signals for analog multiplication with the pulse-width-modulated row elements.

In various embodiments, the processing element 306 may implement two's complement signed number operation using a single capacitor in the integration circuit 318 initially set to a mid-voltage reference. Voltages above the mid-voltage indicate positive results and voltages below the mid-voltage indicate negative results. For example, in a 0V to 1.024V range, a mid-voltage of 512 mV may serve as the zero reference. The ADC array 304 interprets output voltages relative to a threshold voltage, where values below the threshold represent negative numbers and values above the threshold represent positive numbers. The ADC array 304 may output values from 0 to 1023, with interpretation assigning sign based on the threshold such that values below 512 represent negative numbers (−1 to −511) and values above 512 represent positive numbers (1 to 511).

With continued reference to FIG. 3, the ADC array 304 is coupled to the processing array 302 and is configured to digitize the accumulated result from each PE of the plurality of PEs. In various embodiments, the ADC array 304 comprises N parallel ADCs, where N corresponds to a number of the PE columns, and the ADC array 304 is configured to digitize the accumulated result from a respective PE row of the PE rows per conversion cycle. The N² ADC conversions from each processing element may be performed in N cycles with N parallel ADCs, in one cycle with N² ADCs, or using hybrid approaches.

In various embodiments, the analog processing element comprises a first integration capacitor, a second integration capacitor, and a switch configured to selectively couple the output of the pulse-controlled switch 312 to one of the first integration capacitor or the second integration capacitor over successive arithmetic operations. The first integration capacitor is configured to accumulate the product while the second integration capacitor is coupled to the output interface for the extraction. This ping-pong buffering configuration eliminates idle time during fetch operations, as one capacitor may be actively accumulating products for a current matrix operation while the other capacitor is being read out by the ADC array 304 for a previous matrix operation. After completion of an arithmetic operation, the roles of the first integration capacitor and the second integration capacitor are swapped, with the completed capacitor going to conversion while the reset capacitor becomes active for the next arithmetic operation.

FIG. 4 is a diagram 400 illustrating an analog processing element implementation with an integration array located external to the processing array, in accordance with an embodiment of the disclosure. FIG. 4 is explained in conjunction with elements from FIG. 1, FIG. 2, and FIG. 3. The diagram 400 depicts a processing array 402 comprising a plurality of analog processing elements (PEs) arranged in PE rows and PE columns, with processing elements labeled PE_11, PE_12, PE_13 in a first row, PE_21, PE_22, PE_23 in a second row, and PE_31, PE_32, PE_33 in a third row, with ellipses indicating extensibility of the array structure. An integration array 404 is coupled to the processing array 402 and is external to the processing array 402. An ADC array 406 is coupled to the integration array 404 and is configured to digitize the accumulated results from the integration array 404. A digital processing circuit 422 is coupled to the ADC array 406 and is configured to receive and process the digitized results.

With continued reference to FIG. 4, a processing element 408 is shown in expanded detail on the left side of the diagram 400. The processing element 408 includes a current generation circuit 410 configured to generate a current having a magnitude based on a respective column element. A shift register 412 is positioned at the top of the processing element 408 and receives an input signal y₁₁. The shift register 412 is configured to receive and buffer column elements for distribution to the processing element 408. A pulse-controlled switch 414 is coupled to the current generation circuit 410 and is configured to receive a pulse signal PS having a duration based on a respective row element and to pass the current for the duration of the pulse signal. The pulse-controlled switch 414 includes an enable switch 420 labeled EN that controls the output current Iₒᵤₜ from the processing element 408. The enable switch 420 is configured to selectively pass the output current Iₒᵤₜ to the integration array 404 for accumulation and subsequent extraction.

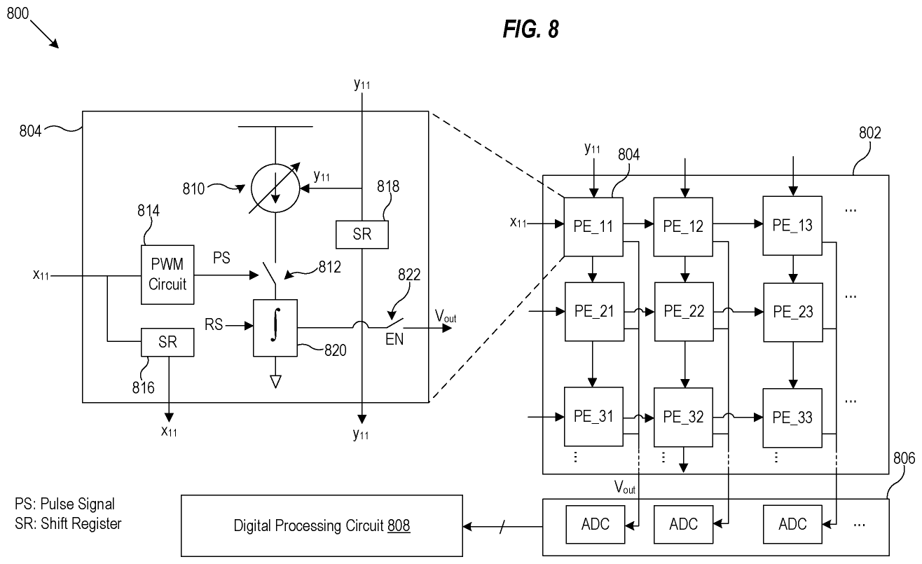

External to the processing element 408, a shift register 418 receives an input signal x₁₁ and couples to a PWM circuit 416. The PWM circuit 416 is configured to convert the respective row element into the pulse signal PS, which is then provided to the pulse-controlled switch 414 within the processing element 408. This configuration places the PWM circuit 416 and the shift register 418 outside the processing array 402, enabling simultaneous application of operands to all PEs in a respective PE row. In this configuration, all PEs subsequent to the processing element 408 in the PE row receive the pulse signal PS directly in the first clock cycle, rather than receiving the row element x₁₁ for internal PWM conversion, in contrast to variations such as the configuration illustrated in FIG. 8 where the PWM circuit 814 is implemented within each PE. The first distribution circuit comprises the PWM circuit 416 for each PE row of the PE rows, providing one PWM circuit per PE row rather than one PWM circuit per PE, reducing the total number of PWM circuits and simplifying the design of the processing element 408 and the processing array 402.

As further shown in FIG. 4, the integration array 404 is external to the processing array 402 and comprises a plurality of integration capacitors. Each integration capacitor of the plurality of integration capacitors is coupled to a respective PE of the plurality of PEs in the processing array 402. Each integration capacitor of the plurality of integration capacitors is configured to accumulate the product from the respective PE. The output currents Iₒᵤₜ from the processing elements in the processing array 402 are routed to corresponding integration capacitors in the integration array 404, where the currents are integrated over the duration of the pulse signal to produce a product of the respective row element and the respective column element, and the products are accumulated over the plurality of clock cycles to produce accumulated results.

The placement of the integration array 404 external to the processing array 402 provides several advantages for the computing device architecture. By relocating the integration capacitors outside the processing elements, the processing element 408 construction is simplified, as each processing element 408 no longer requires internal capacitor circuitry for accumulation. This simplified PE construction reduces the transistor count and circuit complexity within each processing element 408, enabling smaller PE footprints and reduced power consumption per PE. The modular separation of the processing array 402 from the integration array 404 enables denser packing of processing elements within the processing array 402, as the area previously occupied by integration capacitors within each PE is eliminated. This denser packing allows for larger processing arrays within a given silicon area, increasing computational throughput for matrix multiplication operations.

The external integration array 404 further provides improved signal integrity and reduced noise coupling. By physically separating the analog integration capacitors from the digital control circuitry and switching elements within the processing elements, noise generated by switching operations is less likely to couple into the sensitive analog accumulation nodes. The ADC array 406 has improved access to the integration capacitors when the integration capacitors are located in a dedicated region of the integration array 404 rather than distributed within each individual processing element, reducing routing complexity and parasitic capacitance on the signal paths between the integration capacitors and the ADCs. This separation supports modular analog-MAC tiling, where the processing elements may be separated from the integration elements for optimized physical layout. The integration capacitors may be replicated and placed below the processing array 402, with currents routed from PE locations to external capacitor locations in the integration array 404. In some embodiments, the integration capacitors in the integration array 404 may comprise parasitic capacitances inherent in the circuit layout or capacitances typically used in memory array structures for analog compute-in-memory (ACIM) implementations, enabling efficient reuse of existing capacitive structures without requiring dedicated integration capacitor fabrication. Additionally, the external integration array 404 allows for independent optimization of the integration capacitor sizing without impacting the PE layout, enabling larger capacitors for increased dynamic range or smaller capacitors for faster operation based on application requirements.

In various embodiments, the processing element 408 may use differential capacitors in the integration array 404 for signed number operation. In such configurations, a current source on top may be used for positive numbers and a current source on bottom may be used for negative numbers, with two capacitors in the integration array 404 implementing a differential version for analog signed arithmetic. This differential capacitor implementation provides an alternative to the two's complement signed approach using a single capacitor with a mid-voltage reference described with reference to FIG. 3.

The integration array 404 also receives a reset signal RS for resetting accumulated results after extraction. After the resultant matrix is extracted by the output interface comprising the ADC array 406, the reset signal RS is applied to reset the accumulated result at each integration capacitor of the plurality of integration capacitors in the integration array 404. A global reset mechanism may be applied after a complete matrix operation, where all integration capacitors in the integration array 404 reset simultaneously to prepare for a subsequent arithmetic operation. The centralized location of the integration capacitors in the integration array 404 simplifies the reset signal distribution, as a single reset line may be routed to the integration array 404 rather than requiring individual reset connections to each processing element in the processing array 402.

FIG. 5 is a block diagram 500 illustrating a bit-splicing architecture where each vector element is represented as a series of pulses with place value weighting implemented through repeated parallel processing element circuits, in accordance with an embodiment of the disclosure. FIG. 5 is explained in conjunction with elements from FIG. 1, FIG. 2, FIG. 3, and FIG. 4. The block diagram 500 depicts a master PWM (MPWM) circuit 502 and a master processing element (MPE) circuit 504 that together implement the bit-splicing method for improving systolic array speed. The bit-splicing architecture represents a separate embodiment that may be combined with the simultaneous operand application approach described with reference to FIG. 3 and FIG. 4, though the bit-splicing method fundamentally changes the data representation scheme by shifting place value operations into the processing element array hardware.

With continued reference to FIG. 5, the upper portion of the block diagram 500 shows the detailed architecture of the bit-splicing implementation. An input signal x₁₁ enters a deserializer 506, which performs serial-to-parallel conversion of the input data. The deserializer 506 is configured to receive an N-bit word and separate each bit of the N-bit word into a parallel output, where each bit goes to a unique PWM generator. The deserializer 506 is coupled to a pulse width modulation circuit 508, which receives the parallel bit outputs from the deserializer 506 and generates multiple pulse signals labeled PS₀, PS₁, PS₂, through PSₖ₋₁. The pulse width modulation circuit 508 creates N different pulses for each data value instead of one long pulse containing (2^{b}−1)×T_{U}, where b represents the number of bits and T_{U} represents a unit pulse period. This serial-to-parallel conversion and multi-pulse generation forms the basis of the bit-splicing method that enables operands to shift at unit pulse rate rather than at the maximum pulse period rate.

The pulse signals from the pulse width modulation circuit 508 feed into pulse-controlled switches 512 within the master processing element (MPE) circuit 504. A first set of processing elements 510a is coupled to a first pulse-controlled switch that receives the PS₀ signal, a second set of processing elements 510b is coupled to a second pulse-controlled switch that receives the PS₁ signal, a third set of processing elements 510c is coupled to a third pulse-controlled switch that receives the PS₂ signal, and a kth set of processing elements 510k is coupled to a kth pulse-controlled switch that receives the PSₖ₋₁ signal. Each set of processing elements is labeled PE and receives a corresponding y₁₁ input from above, with the processing elements within each set arranged in series and controlled by the y₁₁ operand. The first set of processing elements 510a, the second set of processing elements 510b, the third set of processing elements 510c, and the kth set of processing elements 510k represent a place-weighted parallel processing element array structure, where the first set of processing elements 510a corresponds to PEA with a weight of 1, the second set of processing elements 510b corresponds to 2PEA with a weight of 2, the third set of processing elements 510c corresponds to 4PEA with a weight of 4, and the kth set of processing elements 510k corresponds to 2^{b}PEA with a weight of 2^{b}. The outputs from the processing elements within each respective set are shorted together and passed through the corresponding pulse-controlled switch.

As further shown in FIG. 5, the pulse-controlled switches 512 selectively pass currents from the respective sets of processing elements based on the pulse signals. The outputs from the pulse-controlled switches 512 feed into an integration circuit 514, which accumulates the weighted products from the multiple parallel paths. The integration circuit 514 produces a voltage output 516 labeled Vₒᵤₜ, representing the accumulated result of the bit-spliced multiplication operation. The right side of the block diagram 500 shows the output pulse signals PS₀, PS₁, PS₂, through PSₖ₋₁ that propagate to the next MPE in the row for systolic data flow through the array, while the y₁₁ operand that controls each PE in the series of PEs is passed to the next MPE in the column.

The lower portion of the block diagram 500 shows a simplified representation of the bit-splicing architecture. The master PWM (MPWM) circuit 502 receives the input x₁₁ and generates a set of pulse signals {PSₖ}. The set of pulse signals {PSₖ} feeds into the master processing element (MPE) circuit 504, which also receives the y₁₁ input. The master processing element (MPE) circuit 504 outputs the set of pulse signals {PSₖ} for propagation to the next MPE in the row, the voltage output 516 labeled Vₒᵤₜ, and a buffered y₁₁ signal for propagation to the next MPE in the column for systolic data flow through the array.

The bit-splicing architecture shifts place value of operands inside the processing element array hardware in the current domain, allowing operands to shift at unit pulse rate rather than at the maximum pulse period rate of (2^{b}−1)×T_{U}. In the bit-splicing method, the processing array functions as a DAC array with multiple parallel DAC arrays, where each parallel DAC array corresponds to a different bit position and contributes a place-weighted current to the integration circuit 514. The master processing element (MPE) circuit 504 comprises multiple parallel processing element arrays that implement place-weighted arithmetic, with the shorted outputs from the first set of processing elements 510a, the second set of processing elements 510b, the third set of processing elements 510c, and the kth set of processing elements 510k passed through respective pulse-controlled switches 512 and connected to a summation block implemented by the integration circuit 514.

The bit-splicing method improves speed from N ×(2^{b}−1)×T_{U} to N×T_{U}, where N represents the number of operands in a matrix dimension and b represents the number of bits per operand. This speed improvement is achieved because each operand is represented as B separate unit pulses rather than one long pulse containing (2^{b}−1) unit time periods. The trade-off for this speed improvement is that hardware increases by (2^{b}−1) times, as the processing element array is replicated for each bit position with corresponding place-value weighting. The bit-splicing architecture also results in increased current consumption due to the parallel operation of multiple processing element arrays and requires an N-bit bus input to each processing element instead of a single serial line. The systolic array result is produced in the same N cycles as the simultaneous operand application approach, but each period is a unit pulse T_{U} rather than the maximum pulse period of (2^{b}−1)×T_{U}.

FIG. 6 is a block diagram 600 illustrating a processing array implementation utilizing the bit-splicing architecture of FIG. 5, in accordance with an embodiment of the disclosure. FIG. 6 is explained in conjunction with elements from FIG. 1, FIG. 2, FIG. 3, FIG. 4, and FIG. 5. The block diagram 600 depicts a processing array 602 comprising a plurality of master processing element (MPE) units arranged in a three-by-three grid configuration, with MPE units labeled MPE_11, MPE_12, MPE_13 in a first row, MPE_21, MPE_22, MPE_23 in a second row, and MPE_31, MPE_32, MPE_33 in a third row. Each MPE unit in the processing array 602 implements the bit-splicing architecture described with reference to FIG. 5, where each vector element is represented as a series of pulses with place value weighting implemented through repeated parallel processing element circuits. The processing array 602 functions as a DAC array with multiple parallel DAC arrays, where each parallel DAC array corresponds to a different bit position and contributes a place-weighted current to the integration circuit.

With continued reference to FIG. 6, a first matrix 610 is positioned on the left side of the block diagram 600 and provides row elements to the processing array 602. The first matrix 610 comprises a plurality of row elements arranged as x₁₃, x₁₂, x₁₁ in a first row, x₂₃, x₂₂, x₂₁ in a second row, and x₃₃, x₃₂, x₃₁ in a third row. Each row of the first matrix 610 is coupled to a respective MPWM circuit for conversion into multi-place pulse width modulated signals. A second matrix 612 is positioned at the top of the block diagram 600 and provides column elements to the processing array 602. The second matrix 612 comprises a plurality of column elements arranged as y₁₁, y₂₁, y₃₁ in a first column, y₁₂, y₂₂, y₃₂ in a second column, and y₁₃, y₂₃, y₃₃ in a third column. The column elements of the second matrix 612 are provided to the processing array 602 from above, with each column of the second matrix 612 corresponding to a respective column of MPE units in the processing array 602.

An MPWM 604a receives the first row elements x₁₃, x₁₂, x₁₁ from the first matrix 610 and is configured to generate multi-place pulse width modulated signals for the first row of MPE units in the processing array 602. An MPWM 604b receives the second row elements x₂₃, x₂₂, x₂₁ from the first matrix 610 and is configured to generate multi-place pulse width modulated signals for the second row of MPE units in the processing array 602. An MPWM 604c receives the third row elements x₃₃, x₃₂, x₃₁ from the first matrix 610 and is configured to generate multi-place pulse width modulated signals for the third row of MPE units in the processing array 602. Each of the MPWM 604a, the MPWM 604b, and the MPWM 604c implements the master PWM (MPWM) circuit 502 architecture described with reference to FIG. 5, converting each row element into a set of pulse signals {PSₖ} where each pulse signal corresponds to a different bit position of the row element. For an N-bit word, the MPWM circuit performs serial-to-parallel conversion where each bit goes to a unique PWM generator, creating N different pulses for each data value instead of one long pulse containing (2^{b}−1)×T_{U}.

As further shown in FIG. 6, the first row of the processing array 602 includes MPE_11, MPE_12, and MPE_13, which are coupled to the output of the MPWM 604a. The second row of the processing array 602 includes MPE_21, MPE_22, and MPE_23, which are coupled to the output of the MPWM 604b. The third row of the processing array 602 includes MPE_31, MPE_32, and MPE_33, which are coupled to the output of the MPWM 604c. The MPE units within each row are interconnected horizontally, and the MPE units within each column are interconnected vertically to receive the respective column elements from the second matrix 612. A clock signal CLK is provided to the MPWM 604a, the MPWM 604b, and the MPWM 604c for synchronization of operations across the block diagram 600.

An ADC array 606 is positioned at the bottom of the processing array 602 and comprises a plurality of analog-to-digital converters. Each ADC of the ADC array 606 is coupled to a respective column of the processing array 602 to receive and digitize the accumulated analog results from the MPE units in that column. The N² outputs from the processing array 602 may be digitized in N cycles with N parallel ADCs, in one cycle with N² ADCs, or using a hybrid approach. A digital processing circuit 608 is coupled to the ADC array 606 and is configured to receive the digitized results from the ADC array 606 for further processing and output of the resultant matrix. The clock signal CLK is also provided to the digital processing circuit 608 for synchronization with operations of the processing array 602.

In the bit-splicing architecture illustrated in FIG. 6, the systolic array result is produced using unit pulses instead of longer scaled pulses. The bit-splicing method improves speed from N×(2^{b}−1)×T_{U} to N×T_{U}, where N represents the number of operands in a matrix dimension and b represents the number of bits per operand. The processing array 602 produces the matrix multiplication result in N cycles, where each cycle period is a unit pulse T_{U} rather than the maximum pulse period of (2^{b}−1)×T_{U} required in non-bit-spliced implementations. This speed improvement is achieved because the MPWM 604a, the MPWM 604b, and the MPWM 604c convert each row element into B separate unit pulses corresponding to the B bit positions of the row element, with place value weighting implemented through the parallel processing element circuits within each MPE unit. The trade-off for this speed improvement is that hardware within each MPE unit increases by (2^{b}−1) times compared to a single processing element implementation, with increased current consumption and an N-bit bus input to each MPE unit instead of a single serial line.

After a complete matrix operation, a global reset is applied where all MPE units in the processing array 602 reset simultaneously before the next operation. The global reset prepares the processing array 602 for a subsequent matrix multiplication operation by clearing the accumulated results from the integration circuits within each MPE unit. The reset and reload operations are performed after the ADC array 606 has digitized and extracted the accumulated results from the processing array 602, ensuring that the resultant matrix is captured before the accumulated values are cleared.

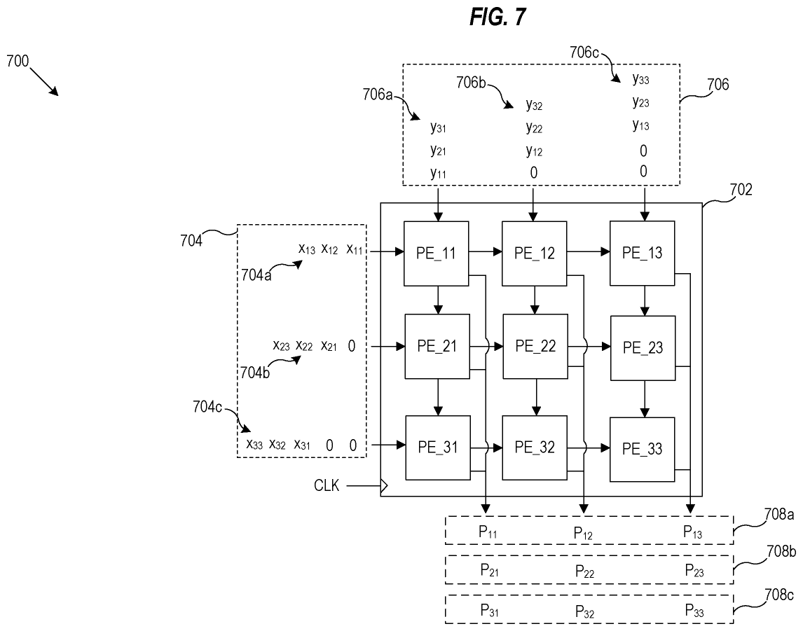

FIG. 7 is a block diagram 700 illustrating a processing array 702 configured for systolic workflow with staggered diagonal data arrangement, in accordance with an embodiment of the disclosure. FIG. 7 is explained in conjunction with elements from FIG. 1. The block diagram 700 depicts the processing array 702 comprising a plurality of processing elements (PEs) arranged in a three-by-three grid configuration, with processing elements labeled PE_11, PE_12, PE_13 in a first row, PE_21, PE_22, PE_23 in a second row, and PE_31, PE_32, PE_33 in a third row. The processing array 702 receives a clock signal CLK that synchronizes the operation of the processing elements. This configuration corresponds to the shift-register-based (SR-based) systolic architecture where operands shift from PE to PE over successive clock cycles, in contrast to the simultaneous operand application approach described with reference to FIG. 2. In this SR-based architecture, a first input node of each PE is configured to receive a first element and to output the first element to a successive PE in a respective PE row of the PE rows after a clock cycle of a plurality of clock cycles, and a second input node of each PE is configured to receive a second element and to output the second element to a successive PE in a respective PE column of the PE columns after the clock cycle.

With continued reference to FIG. 7, a first matrix 704 comprising a plurality of row vectors provides input operands from the left side of the processing array 702. The first matrix 704 comprises a first row vector 704a containing elements x₁₃, x₁₂, and x₁₁, a second row vector 704b containing elements x₂₃, x₂₂, x₂₁, and 0, and a third row vector 704c containing elements x₃₃, x₃₂, x₃₁, 0, and 0. The first row vector 704a, the second row vector 704b, and the third row vector 704c are arranged in a staggered diagonal pattern to ensure proper synchronization of operands at each PE location during computation. The staggered diagonal arrangement introduces zero padding elements that are flushed through the processing array 702 during the pipeline warm-up period. A second matrix 706 comprising a plurality of column vectors provides input operands from the top of the processing array 702. The second matrix 706 comprises a first column vector 706a containing elements y₃₁, y₂₁, y₁₁, and 0, a second column vector 706b containing elements y₃₂, y₂₂, y₁₂, and 0, and a third column vector 706c containing elements y₃₃, y₂₃, y₁₃, 0, and 0. The first column vector 706a, the second column vector 706b, and the third column vector 706c are similarly arranged in the staggered diagonal arrangement corresponding to the arrangement of the first matrix 704. A first input interface is configured to provide the plurality of first elements to PEs in a first PE column of the PE columns in the staggered diagonal arrangement, and a second input interface is configured to provide the plurality of second elements to PEs in a first PE row of the PE rows in the staggered diagonal arrangement.

The staggered diagonal arrangement ensures that when a column element arrives at a particular PE, the corresponding row element arrives simultaneously for correct multiplication. For example, when y₁₁ reaches PE_21, the element x₂₁ arrives at PE_21 at the same clock cycle. The staggered diagonal arrangement introduces a latency of N−2 clock cycles, where N corresponds to a number of the PE rows or a number of the PE columns. For the three-by-three configuration shown in FIG. 7, N equals three, and the latency equals one clock cycle (3−2=1) before the first complete result is available. This latency arises from the first-time dead time due to zeros being flushed from the shifted diagonal data arrangement during pipeline warm-up. The zero padding elements in the second row vector 704b, the third row vector 704c, the first column vector 706a, the second column vector 706b, and the third column vector 706c represent this dead time where PEs receive zero operands that do not contribute to the accumulated result.

As further shown in FIG. 7, the output of the processing array 702 comprises a first output vector 708a containing elements P₁₁, P₁₂, and P₁₃, a second output vector 708b containing elements P₂₁, P₂₂, and P₂₃, and a third output vector 708c containing elements P₃₁, P₃₂, and P₃₃. The first output vector 708a, the second output vector 708b, and the third output vector 708c represent dot products of corresponding row vectors and column vectors. The mathematical relationships for the output elements are shown in the block diagram 700, where each output element represents a dot product of a respective row vector of the plurality of row vectors and a respective column vector of the plurality of column vectors. For example, P₁₁ equals y₁₁×x₁₁+y₂₁×x₁₂+y₃₁×x₁₃. Each PE of the plurality of PEs is configured to multiply the respective row element with the respective column element to produce a product and accumulate the product over the plurality of clock cycles to produce an accumulated result. An output interface is coupled to the processing array 702 and is configured to extract the accumulated result from each PE of the plurality of PEs to output a resultant matrix.

In the SR-based systolic architecture illustrated in FIG. 7, conversion requires N cycles, latency equals N−2 cycles due to data arrangement, and fetch cycles equal N to fetch result data from the processing elements to the output side, assuming N parallel fetch operations where N represents the number of elements in a row vector. MAC cycles equal 2N−2 for matrix-matrix multiplication operations in the systolic array architecture, accounting for both the computation cycles and the pipeline warm-up latency introduced by the staggered diagonal data arrangement. For the three-by-three configuration, MAC cycles equal four (2×3−2=4). Subsequent matrix operations complete every N cycles through pipelined throughput after the initial latency period, as the processing array 702 may begin receiving operands for a new matrix operation while completing the current operation. The computing device may further comprise a reset circuit coupled to the processing array 702, wherein the reset circuit is configured to reset the accumulated result at each PE of the plurality of PEs after the resultant matrix is extracted by the output interface.

In the SR-based systolic architecture, the x and y operands are shifted at a rate defined by the maximum pulse period equal to (2^{b}−1)×T_{U}, where b represents the number of bits of the operand and T_{U} represents a unit pulse period. This shift rate determines the clock cycle duration for the processing array 702, as each PE receives new operands from neighboring PEs at each clock cycle. The first input node of each PE comprises a first shift register configured to delay the first element by the clock cycle before outputting the first element to the successive PE in the respective PE row, and the second input node of each PE comprises a second shift register configured to delay the second element by the clock cycle before outputting the second element to the successive PE in the respective PE column. Each PE of the plurality of PEs further comprises a clock input coupled to the first shift register and the second shift register, where the clock input is configured to synchronize the outputting of the first element and the second element to the successive PE of the respective PE row and the successive PE of the respective PE column, respectively.

FIG. 8 is a diagram 800 illustrating an analog processing element implementation following the systolic workflow of FIG. 7, in accordance with an embodiment of the disclosure. FIG. 8 is explained in conjunction with elements from FIG. 1 and FIG. 7. The diagram 800 depicts a processing array 802 comprising a plurality of analog processing elements (PEs) 804 arranged in PE rows and PE columns, with processing elements labeled PE_11, PE_12, PE_13 in a first row, PE_21, PE_22, PE_23 in a second row, and PE_31, PE_32, PE_33 in a third row, with ellipses indicating extensibility of the array structure. An ADC array 806 is positioned below the processing array 802 and comprises a plurality of analog-to-digital converters configured to digitize the accumulated results from the plurality of processing elements 804. A digital processing circuit 808 is coupled to the ADC array 806 and is configured to receive and process the digitized results to produce the resultant matrix output. This configuration corresponds to the shift-register-based (SR-based) systolic architecture where operands shift from PE to PE over successive clock cycles using the staggered diagonal data arrangement described with reference to FIG. 7. In this SR-based architecture, a first input node of each PE 804 is configured to receive a first element and to output the first element to a successive PE in a respective PE row of the PE rows after a clock cycle of a plurality of clock cycles, and a second input node of each PE 804 is configured to receive a second element and to output the second element to a successive PE in a respective PE column of the PE columns after the clock cycle.

With continued reference to FIG. 8, a processing element 804 is shown in expanded detail on the left side of the diagram 800. The processing element 804 is an analog processing element that comprises a current generation circuit 810 configured to generate a current based on a respective second element. The current generation circuit 810 receives a second element y₁₁ from above and generates a corresponding current signal based on the second element. The current generation circuit 810 may be implemented as a digital-to-current converter (IDAC) that converts the digital second element into an analog current. A shift register 818 is positioned at the top of the processing element 804 and comprises a second input node configured to receive a second element of the plurality of second elements and to output the second element to a successive PE in a respective PE column of the PE columns after a clock cycle of a plurality of clock cycles. The shift register 818 is configured to delay the second element by the clock cycle before outputting the second element to the successive PE in the respective PE column. In this configuration, digital data enters the PE 804, is kept in digital domain via the shift register 818, and is sent to the next PE after one clock cycle delay. Both x and y operands move across the processing array 802 exactly like digital systolic architecture, using shifted inputs across the array matching classical systolic data movement.

The processing element 804 further comprises a pulse width modulation (PWM) circuit 814 coupled to a first input node. The PWM circuit 814 is configured to convert a first element x₁₁ into a pulse signal PS based on the first element. A shift register 816 comprises the first input node configured to receive a first element of the plurality of first elements and to output the first element to a successive PE in a respective PE row of the PE rows after the clock cycle. The shift register 816 is configured to delay the first element by the clock cycle before outputting the first element to the successive PE in the respective PE row. In this SR-based configuration, the PWM circuit 814 is located within each processing element 804, with each PE 804 containing its own PWM circuit for converting the first element into the pulse signal. The processing element 804 further comprises a pulse-controlled switch 812 coupled to the current generation circuit 810. The pulse-controlled switch 812 is configured to receive the pulse signal PS from the PWM circuit 814 and to pass the current for a duration of the pulse signal. Conversion to analog happens inside the PE cell, and each PE 804 requires a clock signal for shift register operation.

As further shown in FIG. 8, the processing element 804 further comprises an integration circuit 820 coupled to an output of the pulse-controlled switch 812. The integration circuit 820 is configured to integrate the current over the duration of the pulse signal to produce a product of the first element and the second element. The integration circuit 820 is further configured to accumulate the product over the plurality of clock cycles to produce an accumulated result. The PE 804 functions as an accumulator performing multiply-and-accumulate operations, where the PE 804 multiplies two current operands, adds the product to the previously stored value, and creates a running sum where operands change while results accumulate. The capacitor in the integration circuit 820 is not reset until all operands for a complete MAC operation have been processed. The processing element 804 further comprises an enable switch 822 coupled to the integration circuit 820. The enable switch 822 is configured to selectively couple the accumulated result to the output interface for the extraction. The enable switch 822 is used for data extraction to the ADC array 806 by bringing one processing element at a time to a common bus wire while all other enable switches are set to inactive, allowing row-by-row result extraction from the processing array 802. In some embodiments, each PE 804 may contain two capacitors for ping-pong buffering, where while one capacitor is active (accumulating), the other is in reset state, eliminating idle time during fetch operations.

In various embodiments, each PE 804 of the plurality of PEs 804 further comprises a clock input coupled to the shift register 816 and the shift register 818. The clock input is configured to synchronize the outputting of the first element and the second element to the successive PE of the respective PE row and the successive PE of the respective PE column, respectively. The clock input receives a clock signal CLK that coordinates the shift register operations within each processing element 804, ensuring that operands are delayed by exactly one clock cycle before being output to successive PEs in the processing array 802. In the SR-based systolic architecture, the x and y operands are shifted at a rate defined by the maximum pulse period equal to (2^{b}−1)×T_{U}, where b represents the number of bits of the operand and T_{U} represents a unit pulse period. This shift rate determines the clock cycle duration for the processing array 802, as each PE 804 receives new operands from neighboring PEs at each clock cycle.

The first input interface (as shown in FIG. 1) is configured to provide the plurality of first elements to PEs in a first PE column of the PE columns in a staggered diagonal arrangement. The second input interface (as shown in FIG. 1) is configured to provide the plurality of second elements to PEs in a first PE row of the PE rows in the staggered diagonal arrangement. The staggered diagonal arrangement ensures that when a second element arrives at a particular PE, the corresponding first element arrives simultaneously for correct multiplication. For example, when y₁₁ reaches PE_21, the element x₂₁ arrives at PE_21 at the same clock cycle. The staggered diagonal arrangement introduces a latency of N−2 clock cycles, where N corresponds to a number of the PE rows or a number of the PE columns. For a three-by-three configuration, N equals three, and the latency equals one clock cycle (3−2=1) before the first complete result is available. This latency arises from the first-time dead time due to zeros being flushed from the shifted diagonal data arrangement during pipeline warm-up. The zero padding elements in the input data arrangement represent this dead time where PEs receive zero operands that do not contribute to the accumulated result.

The output interface comprises the ADC array 806 configured to digitize the accumulated result from each PE 804 of the plurality of PEs 804. The ADC array 806 may comprise N parallel ADCs, where N corresponds to a number of the PE columns, and the ADC array 806 is configured to digitize the accumulated result from a respective PE row of the PE rows per conversion cycle. The N² outputs from the processing array 802 may be digitized in N cycles with N parallel ADCs, in one cycle with N² ADCs, or using a hybrid approach. In the SR-based systolic architecture, conversion requires N cycles, latency equals N−2 cycles due to data arrangement, and fetch cycles equal N to fetch result data from the processing elements to the output side, assuming N parallel fetch operations. MAC cycles equal 2 N−2 for matrix-matrix multiplication operations in the systolic array architecture, accounting for both the computation cycles and the pipeline warm-up latency introduced by the staggered diagonal data arrangement. For the three-by-three configuration, MAC cycles equal four (2×3−2=4). Subsequent matrix operations complete every N cycles through pipelined throughput after the initial latency period, as the processing array 802 may begin receiving operands for a new matrix operation while completing the current operation.

In various embodiments, the computing device 102 further comprises a reset circuit coupled to the processing array 802. The reset circuit is configured to reset the accumulated result at each PE 804 of the plurality of PEs 804 after the resultant matrix is extracted by the output interface. A global reset mechanism may be applied after a complete matrix operation, where all PEs in the processing array 802 reset simultaneously to prepare for a subsequent arithmetic operation. The reset circuit clears the accumulated values in the integration circuit 820 of each processing element 804 after the ADC array 806 has digitized and extracted the accumulated results. The reset and reload operations are required before the next matrix multiplication operation can commence.

Processing element activation is controlled via zero streams in the input data rather than using selective enable signals. PEs receiving zero streams become inactive dead elements with no accumulation, as the multiplication of any operand with zero produces a zero product that does not contribute to the accumulated result. For a processing array 802 that is larger than the matrices being multiplied, the unused PEs may receive zero streams from the first input interface and the second input interface, causing those PEs to function as non-active elements. This approach enables flexible utilization of the processing array 802 for matrices smaller than the array dimensions without requiring individual enable control for each processing element 804. For example, for a 3×3 versus 4×4 or 100×100 array, activation of PE elements can be done by activating corresponding inputs, and if other inputs are zero streams, that PE will not get activated.

In various embodiments, the computing device 102 may be used for Compute-In-Memory implementation where data streams come from memory. The first matrix comprising the plurality of first elements and the second matrix comprising the plurality of second elements may be stored in on-chip or off-chip memory, with weights, kernels, or activations stored in memory locations and streamed to the processing array 802. The first input interface may be configured to receive the first matrix from a memory array, and the second input interface may be configured to receive the second matrix from a memory array. The shift register 816 and the shift register 818 within each processing element 804 receive the streamed data from memory and delay the elements by one clock cycle before outputting to successive PEs, enabling systolic data flow through the processing array 802 for matrix multiplication operations on data retrieved from memory storage.

FIG. 9 is a block diagram 900 illustrating a digital processing element array implementation for matrix multiplication operations, in accordance with an embodiment of the disclosure. FIG. 9 is explained in conjunction with elements from FIG. 1 and FIG. 2. The block diagram 900 depicts a processing array 902 comprising a plurality of processing elements 904 arranged in PE rows and PE columns. The processing array 902 shows a grid configuration with processing elements 904 labeled PE_11, PE_12, PE_13 in a first row, PE_21, PE_22, PE_23 in a second row, and PE_31, PE_32, PE_33 in a third row, with ellipses indicating the processing array 902 may extend to additional rows and columns. The digital processing element array implementation provides an alternative to the analog processing element configurations described with reference to FIG. 3 and FIG. 4 while maintaining the simultaneous operand application approach where operands are concurrently applied to all processing elements 904 in respective PE rows and PE columns at each clock cycle.

With continued reference to FIG. 9, each processing element 904 receives input operands from two directions. A first operand x₁₁ enters horizontally from the left side and is applied to all processing elements 904 in the respective PE row. A second operand y₁₁ enters vertically from the top and is applied to all processing elements 904 in the respective PE column. The processing elements 904 are interconnected with horizontal connections passing data rightward between adjacent elements in the same row and vertical connections passing data downward between adjacent elements in the same column. A first distribution circuit is configured to concurrently apply, at each clock cycle of a plurality of clock cycles, a respective row element from each row vector of a first matrix to all processing elements 904 of the respective PE row. A second distribution circuit is configured to concurrently apply, at each clock cycle of the plurality of clock cycles, a respective column element from each column vector of a second matrix to all processing elements 904 in the respective PE column.

As further shown in FIG. 9, an expanded view of the processing element 904 is shown on the left side of the block diagram 900. Each processing element 904 of the plurality of processing elements 904 is a digital processing element. The digital processing element comprises a digital multiplier 906 and a digital accumulator 908. The digital multiplier 906 receives the first operand x₁₁ and the second operand y₁₁ as inputs. The digital multiplier 906 is configured to multiply the respective row element with the respective column element to produce a product. The digital accumulator 908 is coupled to the digital multiplier 906. The digital accumulator 908 is configured to accumulate the product over a plurality of clock cycles to produce an accumulated result Pₒᵤₜ. Each processing element 904 of the plurality of processing elements 904 is configured to multiply the respective row element with the respective column element into a product and accumulate the product over the plurality of clock cycles to produce an accumulated result.

The outputs from the processing elements 904 in the bottom row of the processing array 902 are labeled Pₒᵤₜ and feed into a digital processing circuit 910. The digital processing circuit 910 is coupled to the processing array 902 and is configured to receive the accumulated results from each processing element 904 of the plurality of processing elements 904. The digital processing circuit 910 is further configured to output a resultant matrix representing the product of the input matrices. An output interface is coupled to the processing array 902 and is configured to extract the accumulated result from each processing element 904 of the plurality of processing elements 904 to output the resultant matrix. The resultant matrix represents an output of an arithmetic operation between the first matrix and the second matrix.

In various embodiments, the digital processing element may use two accumulator registers for ping-pong operation, analogous to the two capacitors in the analog implementation described with reference to FIG. 3. In the ping-pong operation, a first accumulator register is configured to accumulate the product while a second accumulator register is coupled to the output interface for extraction of a previously computed accumulated result. After completion of an arithmetic operation, the roles of the first accumulator register and the second accumulator register are swapped, with the completed accumulator register going to extraction while the cleared accumulator register becomes active for the next arithmetic operation. This ping-pong buffering configuration eliminates idle time during fetch operations, as one accumulator register may be actively accumulating products for a current matrix operation while the other accumulator register is being read out by the digital processing circuit 910 for a previous matrix operation.

The digital implementation illustrated in FIG. 9 maintains the simultaneous operand application approach where operands are concurrently applied to all processing elements 904 in respective PE rows and PE columns rather than shifting operands from PE to PE as in traditional systolic arrays. The first distribution circuit and the second distribution circuit are external to the processing array 902, with shift registers located externally to the processing array 902 rather than within each processing element 904. Each processing element 904 of the plurality of processing elements 904 receives the respective row element as a buffered signal from the first distribution circuit and receives the respective column element as a buffered signal from the second distribution circuit. The plurality of clock cycles comprises N clock cycles, where N corresponds to a number of row elements in each row vector of the plurality of row vectors. The simultaneous operand application approach eliminates the pipeline warm-up latency that exists in traditional shift-register-based systolic architectures, where a staggered diagonal data arrangement introduces a latency of N−2 clock cycles before the first complete result is available.

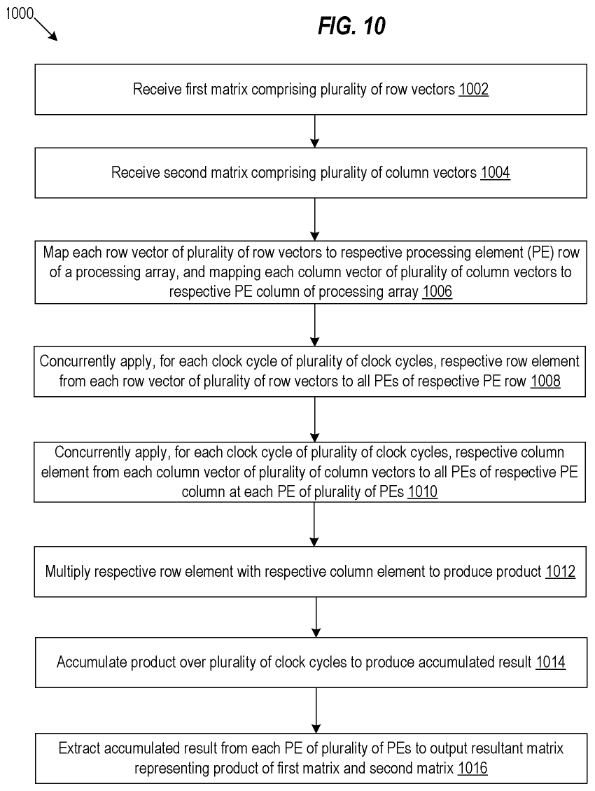

FIG. 10 is a flowchart 1000 depicting a method for performing matrix multiplication, in accordance with an embodiment of the disclosure. FIG. 10 is explained in conjunction with elements from FIG. 1, FIG. 2, FIG. 3, FIG. 4, FIG. 8, and FIG. 9. With reference to FIG. 10, there is shown the flowchart 1000. The operations of the exemplary method may be executed by any computing system, for example, by the computing device 102 of FIG. 1. The operations of the flowchart 1000 may start at 1002.

At 1002, the operations include receiving a first matrix comprising a plurality of row vectors. In an embodiment of the disclosure, the computing device 102 is configured to receive the first matrix 104a comprising the plurality of row vectors via the first input interface 104. Each row vector of the plurality of row vectors contains a plurality of row elements that are to be used as operands in the matrix multiplication operation. The first matrix 104a may be received from external memory, a data bus, or other data sources. As described with reference to FIG. 2, the first matrix 202 comprises the first row vector 202a, the second row vector 202b, and the third row vector 202c, where each row vector corresponds to a respective PE row of the processing array 112. The operations proceed to 1004.

At 1004, the operations include receiving a second matrix comprising a plurality of column vectors. In an embodiment of the disclosure, the computing device 102 is configured to receive the second matrix 106a comprising the plurality of column vectors via the second input interface 106. Each column vector of the plurality of column vectors contains a plurality of column elements that are to be used as operands in the matrix multiplication operation. The second matrix 106a may be received from external memory, a data bus, a memory array, or other data sources. As described with reference to FIG. 2, the second matrix 204 comprises the first column vector 204a, the second column vector 204b, and the third column vector 204c, where each column vector corresponds to a respective PE column of the processing array 112. In some embodiments, the second input interface 106 is configured to receive the second matrix 106a from a memory array, enabling compute-in-memory implementations where weights, kernels, or activations may be stored in the memory location and streamed to the processing array 112. The operations proceed to 1006.

At 1006, the operations include mapping each row vector of the plurality of row vectors to a respective processing element (PE) row of a processing array, and mapping each column vector of the plurality of column vectors to a respective PE column of the processing array. The processing array comprises a plurality of PEs arranged in the PE rows and the PE columns. In an embodiment of the disclosure, the processing array 112 comprises the plurality of processing elements 114 arranged in the PE rows 116 and the PE columns 118, as shown in FIG. 1. Each row vector of the plurality of row vectors corresponds to a respective PE row 116 of the PE rows 116, and each column vector of the plurality of column vectors corresponds to a respective PE column 118 of the PE columns 118. For example, as shown in FIG. 2, the first row vector 202a is mapped to the PE row containing processing elements PE_11, PE_12, and PE_13, the second row vector 202b is mapped to the PE row containing processing elements PE_21, PE_22, and PE_23, and the third row vector 202c is mapped to the PE row containing processing elements PE_31, PE_32, and PE_33. Similarly, the first column vector 204a is mapped to the PE column containing processing elements PE_11, PE_21, and PE_31, the second column vector 204b is mapped to the PE column containing processing elements PE_12, PE_22, and PE_32, and the third column vector 204c is mapped to the PE column containing processing elements PE_13, PE_23, and PE_33. The operations proceed to 1008.

At 1008, the operations include, for each clock cycle of a plurality of clock cycles, concurrently applying a respective row element from each row vector of the plurality of row vectors to all PEs of the respective PE row. In an embodiment of the disclosure, the first distribution circuit 108 is configured to concurrently apply, at each clock cycle of the plurality of clock cycles, a respective row element from each row vector of the plurality of row vectors to all PEs of the respective PE row 116. The first distribution circuit 108 may comprise a first shift register circuit configured to sequentially select successive row elements from each row vector of the plurality of row vectors over the plurality of clock cycles. For analog implementations as described with reference to FIG. 3 and FIG. 4, the first distribution circuit 108 comprises the PWM circuit 314 or the PWM circuit 416 configured to convert the respective row element into a pulse signal, wherein the first distribution circuit 108 comprises the PWM circuit for each PE row of the PE rows. The concurrent application of row elements to all PEs in a respective PE row enables simultaneous operand application where operands are broadcast to all PEs in a respective row simultaneously, rather than shifting operands from PE to PE as in traditional systolic arrays. The operations proceed to 1010.

At 1010, the operations include, for each clock cycle of the plurality of clock cycles, concurrently applying a respective column element from each column vector of the plurality of column vectors to all PEs of the respective PE column. In an embodiment of the disclosure, the second distribution circuit 110 is configured to concurrently apply, at each clock cycle of the plurality of clock cycles, a respective column element from each column vector of the plurality of column vectors to all PEs in the respective PE column 118. The second distribution circuit 110 may comprise a second shift register circuit configured to sequentially select successive column elements from each column vector of the plurality of column vectors over the plurality of clock cycles. The first distribution circuit 108 and the second distribution circuit 110 may be external to the processing array 112, with shift registers located externally to the processing array 112 rather than within each PE. Each PE of the plurality of PEs receives the respective row element as a buffered signal from the first distribution circuit 108 and receives the respective column element as a buffered signal from the second distribution circuit 110. The operations proceed to 1012.

At 1012, the operations include, at each PE of the plurality of PEs, multiplying the respective row element with the respective column element to produce a product. In an embodiment of the disclosure, each PE of the plurality of PEs is configured to multiply the respective row element with the respective column element to produce a product. For analog implementations as described with reference to FIG. 3 and FIG. 4, each PE is an analog processing element that comprises the current generation circuit 308 or the current generation circuit 410 configured to generate a current having a magnitude based on the respective column element, and the pulse-controlled switch 312 or the pulse-controlled switch 414 configured to receive a pulse signal having a duration based on the respective row element and to pass the current for the duration of the pulse signal. The integration circuit 318 is configured to integrate the current over the duration of the pulse signal to output a voltage signal representing the product of the respective row element and the respective column element. For digital implementations as described with reference to FIG. 9, each PE is a digital processing element that comprises the digital multiplier 906 configured to multiply the respective row element with the respective column element to produce the product. The operations proceed to 1014.

At 1014, the operations include, at each PE of the plurality of PEs, accumulating the product over the plurality of clock cycles to produce an accumulated result. In an embodiment of the disclosure, each PE of the plurality of PEs is configured to accumulate the product over the plurality of clock cycles to produce an accumulated result. The PE functions as an accumulator performing multiply-and-accumulate operations, where the PE multiplies two current operands, adds the product to the previously stored value, and creates a running sum where operands change while results accumulate. For analog implementations, the integration circuit 318 is configured to accumulate the product over the plurality of clock cycles to produce the accumulated result. The capacitor in the integration circuit 318 is not reset until all operands for a complete MAC operation have been processed. For digital implementations, the digital accumulator 908 is configured to accumulate the product over the plurality of clock cycles to produce the accumulated result. The plurality of clock cycles comprises N clock cycles, where N corresponds to a number of row elements in each row vector of the plurality of row vectors. The accumulated result at each PE of the plurality of PEs represents a dot product of a respective row vector of the plurality of row vectors and a respective column vector of the plurality of column vectors. For example, PE₁₁ computes x₁₁·y₁₁+x₁₂·y₂₁+x₁₃·y₃₁, PE₁₂ computes x₁₁·y₁₂+x₁₂·y₂₂+x₁₃·y₃₂, and PE₂₁ computes x₂₁·y₁₁+x₂₂·y₂₁+x₂₃·y₃₁. The operations proceed to 1016.

At 1016, the operations include extracting the accumulated result from each PE of the plurality of PEs to output a resultant matrix representing a product of the first matrix and the second matrix. In an embodiment of the disclosure, the output interface 120 is coupled to the processing array 112 and is configured to extract the accumulated result from each PE of the plurality of PEs to output the resultant matrix 126. The resultant matrix 126 represents an output of an arithmetic operation between the first matrix 104a and the second matrix 106a. For analog implementations, the output interface 120 comprises the ADC array 304 or the ADC array 406 configured to digitize the accumulated result from each PE of the plurality of PEs. The ADC array may comprise N parallel ADCs, where N corresponds to a number of the PE columns, and the ADC array is configured to digitize the accumulated result from a respective PE row of the PE rows per conversion cycle. The N² outputs from the processing array may be digitized in N cycles with N parallel ADCs, in one cycle with N² ADCs, or using a hybrid approach. For analog implementations, each PE may further comprise the enable switch 320 or the enable switch 420 configured to selectively couple the accumulated result to the output interface for the extraction, wherein the enable switch brings one element at a time to a common bus wire for row-by-row result extraction. The digital processing circuit 122 processes the stream of accumulated results 124 to produce the resultant matrix 126. As shown in FIG. 2, the output of the processing array 112 comprises the first output vector 206a, the second output vector 206b, and the third output vector 206c, which collectively represent the resultant matrix. After extraction of the resultant matrix, a reset circuit coupled to the processing array 112 may reset the accumulated result at each PE of the plurality of PEs to prepare for a subsequent matrix multiplication operation. A global reset mechanism may be applied after a complete matrix operation, where all PEs reset simultaneously before the next operation.

Reference throughout this specification to “an example” means that a particular feature, structure, or characteristic described in connection with the example is included in at least one embodiment of the present invention. Thus, appearances of the phrase “in an example” in various places throughout this specification are not necessarily all referring to the same embodiment.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on its presentation in a common group without indications to the contrary. In addition, various embodiments and examples of the present invention may be referred to herein along with alternatives for the various components thereof. It is understood that such embodiments, examples, and alternatives are not to be construed as de facto equivalents of one another but are to be considered as separate and autonomous representations of the present invention.

Although the foregoing has been described in some detail for purposes of clarity, it will be apparent that certain changes and modifications may be made without departing from the principles thereof. It should be noted that there are many alternative ways of implementing both the processes and apparatuses described herein. Accordingly, the present embodiments are to be considered illustrative and not restrictive, and the invention is not to be limited to the details given herein but may be modified within the scope and equivalents of the appended claims.

Those having skill in the art will appreciate that many changes may be made to the details of the above-described embodiments without departing from the underlying principles of the invention. The scope of the present invention should, therefore, be determined only by the following claims.

What is claimed is:

1. A computing device, comprising:
a first input interface configured to receive a first matrix comprising a plurality of row vectors;
a second input interface configured to receive a second matrix comprising a plurality of column vectors;
a processing array comprising a plurality of processing elements (PEs) arranged in PE rows and PE columns,
wherein each row vector of the plurality of row vectors corresponds to a respective PE row of the PE rows, and each column vector of the plurality of column vectors corresponds to a respective PE column of the PE columns;
a first distribution circuit coupled to the first input interface and the processing array, wherein the first distribution circuit is configured to concurrently apply, at each clock cycle of a plurality of clock cycles, a respective row element from each row vector of the plurality of row vectors to all PEs of the respective PE row;
a second distribution circuit coupled to the second input interface and the processing array, wherein the second distribution circuit is configured to concurrently apply, at each clock cycle of the plurality of clock cycles, a respective column element from each column vector to all PEs in the respective PE column;
wherein each PE of the plurality of PEs is configured to multiply the respective row element with the respective column element into a product and accumulate the product over the plurality of clock cycles to produce an accumulated result; and
an output interface coupled to the processing array, wherein the output interface is configured to extract the accumulated result from each PE of the plurality of PEs to output a resultant matrix, and the resultant matrix represents an output of an arithmetic operation between the first matrix and the second matrix.

2. The computing device according to claim 1, wherein the first distribution circuit comprises a first shift register circuit configured to sequentially select successive row elements from each row vector of the plurality of row vectors over the plurality of clock cycles, and
wherein the second distribution circuit comprises a second shift register circuit configured to sequentially select successive column elements from each column vector of the plurality of column vectors over the plurality of clock cycles.

3. The computing device according to claim 1, wherein the first distribution circuit and the second distribution circuit are external to the processing array.

4. The computing device according to claim 1, further comprising a reset circuit coupled to the processing array, wherein each PE of the plurality of PEs is configured to:
maintain the accumulated result during the plurality of clock cycles; and
reset the accumulated result at each PE of the plurality of PEs after the plurality of clock cycles,
wherein the accumulated result at each PE of the plurality of PEs represents a dot product of a respective row vector of the plurality of row vectors and a respective column vector of the plurality of column vectors.

5. The computing device according to claim 1, wherein each PE of the plurality of PEs is an analog processing element that comprises:
a current generation circuit configured to generate a current having a magnitude based on the respective column element;
a pulse-controlled switch coupled to the current generation circuit, wherein the pulse-controlled switch is configured to receive a pulse signal having a duration based on the respective row element; and
an integration circuit coupled to an output of the pulse-controlled switch,
wherein the pulse-controlled switch is configured to pass the current via the output to the integration circuit for the duration of the pulse signal, and
the integration circuit is configured to integrate the current over the duration of the pulse signal to output a voltage signal representing the product of the respective row element and the respective column element.

6. The computing device according to claim 5, wherein the first distribution circuit comprises a pulse width modulation (PWM) circuit configured to convert the respective row element into the pulse signal, and wherein the first distribution circuit comprises the PWM circuit for each PE row of the PE rows.

7. The computing device according to claim 5, wherein the analog processing element further comprises an enable switch configured to selectively pass the accumulated result to the output interface for the extraction.

8. The computing device according to claim 5, wherein the analog processing element comprises a first integration capacitor, a second integration capacitor, and a switch configured to selectively couple the output of the pulse-controlled switch to one of the first integration capacitor or the second integration capacitor over successive arithmetic operations, and
wherein the first integration capacitor is configured to accumulate the product while the second integration capacitor is coupled to the output interface for the extraction.

9. The computing device according to claim 5, wherein the output interface comprises an analog-to-digital converter (ADC) array coupled to the processing array, and the ADC array is configured to digitize the accumulated result from each PE of the plurality of PEs.

10. The computing device according to claim 9, wherein the ADC array comprises N parallel ADCs, N corresponds to a number of the PE columns, and the ADC array is configured to digitize the accumulated result from a respective PE row of the PE rows per conversion cycle.

11. The computing device according to claim 1, further comprising an integration array external to the processing array, wherein:
the integration array comprises a plurality of integration capacitors,
each integration capacitor of the plurality of integration capacitors is coupled to a respective PE of the plurality of PEs, and
each integration capacitor of the plurality of integration capacitors is configured to accumulate the product from the respective PE.

12. The computing device according to claim 1, wherein each PE of the plurality of PEs is a digital processing element, and the digital processing element comprises:
a digital multiplier configured to multiply the respective row element with the respective column element to produce the product; and
an accumulator configured to accumulate the product over the plurality of clock cycles to produce the accumulated result.

13. The computing device according to claim 1, wherein each PE of the plurality of PEs receives the respective row element as a buffered signal from the first distribution circuit and receives the respective column element as a buffered signal from the second distribution circuit.

14. The computing device according to claim 1, wherein the plurality of clock cycles comprises N clock cycles, where N corresponds to a number of row elements in each row vector of the plurality of row vectors.

15. The computing device according to claim 1, wherein the arithmetic operation is one of a matrix vector multiplication or a matrix-matrix multiplication operation.

16. The computing device according to claim 1, wherein the second input interface is configured to receive the second matrix from a memory array, and the second distribution circuit is configured to stream column elements of the second matrix from the memory to the processing array.

17. A computing device, comprising:
a first input interface configured to receive a first matrix comprising a plurality of first elements;
a second input interface configured to receive a second matrix comprising a plurality of second elements;
a processing array comprising a plurality of analog processing elements (PEs) arranged in PE rows and PE columns, wherein each PE of the plurality of PEs comprises:
a first input node configured to receive a first element of the plurality of first elements and to output the first element to a successive PE in a respective PE row of the PE rows after a clock cycle of a plurality of clock cycles;
a pulse width modulation (PWM) circuit coupled to the first input node, the PWM circuit configured to convert the first element into a pulse signal based on the first element;
a second input node configured to receive a second element of the plurality of second elements and to output the second element to a successive PE in a respective PE column of the PE columns after the clock cycle;
a current generation circuit coupled to the second input node, wherein the current generation circuit is configured to generate a current based on the second element;
a pulse-controlled switch coupled to the current generation circuit, wherein the pulse-controlled switch is configured to receive the pulse signal from the PWM circuit and to pass the current for a duration of the pulse signal; and
an integration circuit coupled to an output of the pulse-controlled switch, wherein the integration circuit is configured to:
integrate the current over the duration of the pulse signal to produce a product of the first element and the second element; and
accumulate the product over the plurality of clock cycles to produce an accumulated result; and
an output interface coupled to the processing array, wherein the output interface is configured to extract the accumulated result from each PE of the plurality of PEs to output a resultant matrix.

18. The computing device according to claim 17, wherein the first input node comprises a first shift register configured to delay the first element by the clock cycle before outputting the first element to the successive PE in the respective PE row, and
wherein the second input node comprises a second shift register configured to delay the second element by the clock cycle before outputting the second element to the successive PE in the respective PE column.

19. The computing device according to claim 18, wherein each PE of the plurality of PEs further comprises a clock input coupled to the first shift register and the second shift register, and wherein the clock input is configured to synchronize the outputting of the first element and the second element to the successive PE of the respective PE row and the successive PE of the respective PE row, respectively.

20. The computing device according to claim 17, wherein the first input interface is configured to provide the plurality of first elements to PEs in a first PE column of the PE columns in a staggered diagonal arrangement, and the second input interface is configured to provide the plurality of second elements to PEs in a first PE row of the PE rows in the staggered diagonal arrangement.

21. The computing device according to claim 20, wherein the staggered diagonal arrangement introduces a latency of N−2 clock cycles, where N corresponds to a number of the PE rows or a number of the PE columns.

22. The computing device according to claim 17, wherein each PE of the plurality of PEs further comprises an enable switch coupled to the integration circuit, and wherein the enable switch is configured to selectively couple the accumulated result to the output interface for the extraction.

23. The computing device according to claim 17, wherein the output interface comprises an analog-to-digital converter (ADC) array configured to digitize the accumulated result from each PE of the plurality of PEs.

24. The computing device according to claim 17, further comprising a reset circuit coupled to the processing array, wherein the reset circuit is configured to reset the accumulated result at each PE of the plurality of PEs after the resultant matrix is extracted by the output interface.

25. A method for performing matrix multiplication, the method comprising:
receiving a first matrix comprising a plurality of row vectors;
receiving a second matrix comprising a plurality of column vectors;
mapping each row vector of the plurality of row vectors to a respective processing element (PE) row of a processing array, and mapping each column vector of the plurality of column vectors to a respective PE column of the processing array,
wherein the processing array comprises a plurality of PEs arranged in the PE rows and the PE columns;
for each clock cycle of a plurality of clock cycles:
concurrently applying a respective row element from each row vector of the plurality of row vectors to all PEs of the respective PE row; and
concurrently applying a respective column element from each column vector of the plurality of column vectors to all PEs of the respective PE column;
at each PE of the plurality of PEs:
multiplying the respective row element with the respective column element to produce a product; and
accumulating the product over the plurality of clock cycles to produce an accumulated result; and
extracting the accumulated result from each PE of the plurality of PEs to output a resultant matrix representing a product of the first matrix and the second matrix.
